(19) United States
(12) Patent Application Publication
(10) Pub. No.: US 2025/0185182 A1
(43) Pub. Date: Jun. 5, 2025

(54) DISPLAY DEVICE

(71) Applicant: Samsung Display Co., Ltd., Yongin-si (KR)

(72) Inventors: SOJEONG LA, Yongin-si (KR); JAIKU SHIN, Yongin-si (KR); Jihye SHIN, Yongin-si (KR); GYEONGHO JEONG, Yongin-si (KR); SUNG CHUL CHOI, Yongin-si (KR)

(21) Appl. No.: 18/954,190

(22) Filed: Nov. 20, 2024

(30) Foreign Application Priority Data
Dec. 4, 2023 (KR) 10-2023-0173162

(51) Int. Cl. H05K 5/00

(52) U.S. Cl. CPC H05K 5/0018

(57) ABSTRACT

A display device includes: a display module; a support plate below the display module, and including a first support plate, a second support plate, and a folding portion between the first and second support plates; a digitizer below the support plate; and a shielding layer in contact with a lower surface of the digitizer, and having: a first opening adjacent to the first support plate and overlapping with the folding portion; and a second opening adjacent to the second support plate and overlapping with the folding portion.

### CROSS-REFERENCE TO RELATED APPLICATIONS

The present application claims priority to and the benefit of Korean Patent Application No. 10-2023-0173162, filed on Dec. 4, 2023, in the Korean Intellectual Property Office, the entire disclosure of which is incorporated by reference herein.

### BACKGROUND

### 1. Field

Aspects of embodiments of the present disclosure relate to a display device.

### 2. Description to the Related Art

Electronic devices, such as smart phones, digital cameras, laptop computers, navigation systems, and smart televisions, that provide images to a user include a display device for displaying the images. The display device generates images, and provides the images to a user through a display screen.

Recently, with the development of display device technology, various kinds of display devices are being developed. For example, various flexible display devices, which may be folded, rolled, or transformed into curved shapes, are being developed. Flexible display devices, which may be transformed into various shapes, are easy to carry and improve user convenience.

The above information disclosed in this Background section is for enhancement of understanding of the background of the present disclosure, and therefore, it may contain information that does not constitute prior art.

### SUMMARY

Among flexible display devices, a foldable display device includes a display module that is folded based on a folding axis extending in one direction. The display module may be folded or unfolded around the folding axis. The display module includes a folding region that is bent in a folding operation. The folding region may be bent so as to have a suitable curvature radius (e.g., a predetermined curvature radius).

One or more embodiments of the present disclosure may be directed to a display device that may expand the curvature radius of a bent portion of a folding portion that is folded into a dumbbell shape.

According to one or more embodiments of the present disclosure, a display device includes: a display module; a support plate below the display module, and including a first support plate, a second support plate, and a folding portion between the first and second support plates; a digitizer below the support plate; and a shielding layer in contact with a lower surface of the digitizer, and having: a first opening adjacent to the first support plate and overlapping with the folding portion; and a second opening adjacent to the second support plate and overlapping with the folding portion.

In an embodiment, the first support plate, the folding portion, and the second support plate may be located along a first direction; and the first opening and the second opening may extend in a second direction crossing the first direction.

In an embodiment, the first opening and the second opening may open the shielding layer in the second direction to separate the shielding layer.

In an embodiment, the digitizer may include a first digitizer overlapping with the first support plate and a portion of the folding portion adjacent to the first support plate; and a second digitizer overlapping with the second support plate and a portion of the folding portion adjacent to the second support plate. The shielding layer may include: a first shielding layer in contact with the lower surface of the first digitizer, and having the first opening defined therein; and a second shielding layer spaced from the first shielding layer, in contact with the lower surface of the second digitizer, and having the second opening defined therein.

In an embodiment, the folding portion may include: a curved surface portion; a first reverse curvature portion between the first support plate and the curved surface portion; and a second reverse curvature portion between the second support plate and the curved surface portion. When the folding portion is folded, the curved surface portion may be bent to have a curvature, and the first and second reverse curvature portions may be bent in a direction opposite to that of the curved surface portion.

In an embodiment, the first opening may overlap with a portion of the first reverse curvature portion having the largest curvature from among the first reverse curvature portion.

In an embodiment, the second opening may overlap with a portion of the second reverse curvature portion having the largest curvature from among the second reverse curvature portion.

In an embodiment, the first shielding layer may include a first curved surface portion overlapping with the first reverse curvature portion and bent together with the first reverse curvature portion when the folding portion is folded; and the first opening may be in a central portion of the first curved surface portion.

In an embodiment, the second shielding layer may include a second curved surface portion overlapping with the second reverse curvature portion and bent together with the second reverse curvature portion when the folding portion is folded; and the second opening may be in a central portion of the second curved surface portion.

In an embodiment, the first opening may overlap with the entire first reverse curvature portion; and the second opening may overlap with the entire second reverse curvature portion.

In an embodiment, the first opening may include a plurality of first openings; the second opening may include a plurality of second openings; the first shielding layer may include a first bending extension portion overlapping with the folding portion; the second shielding layer may include a second bending extension portion overlapping with the folding portion and located in a direction parallel to the first bending extension portion; the plurality of first openings may be in the first bending extension portion; and the plurality of second openings may be in the second bending extension portion.

In an embodiment, the first support plate, the folding portion, and the second support plate may be located along a first direction; the folding portion may be folded around a folding axis extending in a second direction crossing the first direction; and the plurality of first and second openings may be located along a first diagonal direction crossing the first and second directions and a second diagonal direction crossing the first diagonal direction on a plane defined by the first and second directions.

In an embodiment, the first and second openings may extend longer in the second direction than in the first direction.

In an embodiment, the first and second openings may have a circular shape or a polygonal shape.

In an embodiment, the first bending extension portion may include: a first curved surface portion overlapping with the first reverse curvature portion and bent together with the first reverse curvature portion when the folding portion is folded; and a first flat extension portion overlapping with the folding portion and extending in a flat state from the first curved surface portion. The second bending extension portion may include: a second curved surface portion overlapping with the second reverse curvature portion and bent together with the second reverse curvature portion when the folding portion is folded; and a second flat extension portion overlapping with the folding portion and extending in a flat state from the second curved surface portion. First and second openings in the first and second curved surface portions from among the plurality of first and second openings may be larger than first and second openings in the first and second flat extension portions from among the plurality of first and second openings.

In an embodiment, the display device may further include: a first wing plate below the folding portion; a second wing plate below the folding portion and located in a direction parallel to the first wing plate; and a folding support portion connected to the second wing plate and extending onto the first wing plate. The first shielding layer may include a first bending extension portion overlapping with the folding portion; the second shielding layer may include a second bending extension portion overlapping with the folding portion and located in a direction parallel to the first bending extension portion; the first wing plate may be located below the first bending extension portion; the second wing plate may be located below the second bending extension portion; the folding support portion may be located between the first wing plate and the first bending extension portion and between the second wing plate and the second bending extension portion; and the folding support portion may extend to be adjacent to a boundary between the first support plate and the folding portion and a boundary between the second support plate and the folding portion.

In an embodiment, the shielding layer may include a magnetic metal powder.

In an embodiment, an edge of the shielding layer may overlap with an edge of the digitizer.

According to one or more embodiments of the present disclosure, a display device includes: a display module; a support plate below the display module, and including a first non-folding portion, a second non-folding portion, and a folding portion between the first and second non-folding portions; a digitizer below the support plate; and a shielding layer in contact with a lower surface of the digitizer. The folding portion includes: a curved surface portion; a first reverse curvature portion between the first non-folding portion and the folding portion; and a second reverse curvature portion between the second non-folding portion and the folding portion. When the folding portion is folded, the curved surface portion is bent to have a curvature, and the first and second reverse curvature portions are bent in a direction opposite to the curved surface portion. A first opening overlapping with a portion of the first reverse curvature portion having the largest curvature from among the first reverse curvature portion and a second opening overlapping with a portion of the second reverse curvature portion having the largest curvature from among the second reverse curvature portion are defined in the shielding layer.

According to one or more embodiments of the present disclosure, a display device includes: a display module; a support plate below the display module, and including a first non-folding portion, a second non-folding portion, and a folding portion between the first and second non-folding portions; a digitizer below the support plate; and a shielding layer in contact with a lower surface of the digitizer. The folding portion includes: a curved surface portion; a first reverse curvature portion between the first non-folding portion and the folding portion; and a second reverse curvature portion between the second non-folding portion and the folding portion. When the folding portion is folded, the curved surface portion is bent to have a curvature, and the first and second reverse curvature portions are bent in a direction opposite to the curved surface portion. A first opening overlapping with a central portion of the first reverse curvature portion and a second opening overlapping with a central portion of the second reverse curvature portion are defined in the shielding layer.

### BRIEF DESCRIPTION OF THE FIGURES

The above and other aspects and features of the present disclosure will be more clearly understood from the following detailed description of the illustrative, non-limiting embodiments with reference to the accompanying drawings, in which:

FIG. 1 is a perspective view of a display device according to an embodiment of the present disclosure;

FIG. 2 illustrates a folded state of the display device illustrated in FIG. 1;

FIG. 3 is an exploded perspective view of the display device illustrated in FIG. 1;

FIG. 4 is a block diagram of the display device illustrated in FIG. 3;

FIG. 5 illustrates a cross-sectional view of an electronic panel including a display panel illustrated in FIG. 3;

FIG. 6 illustrates a cross-sectional view of the display panel illustrated in FIG. 5;

FIG. 7 is a plan view of the display panel illustrated in FIG. 3;

FIG. 8 illustrates a cross-sectional view of the electronic panel corresponding to one pixel illustrated in FIG. 7;

FIG. 9 is a cross-sectional view taken along the line I-I′ illustrated in FIG. 7;

FIG. 10A is a cross-sectional view taken along the line II-II′ illustrated in FIG. 7;

FIG. 10B illustrates a bent state of a bending region illustrated in FIG. 10A;

FIG. 11 is a perspective view of a support plate illustrated in FIG. 9;

FIG. 12 is an enlarged plan view of the region AA illustrated in FIG. 11;

FIG. 13 is a plan view of a shielding layer illustrated in FIG. 9;

FIG. 14 illustrates a folded state of the display device illustrated in FIG. 9;

FIG. 15 illustrates a folded state of a comparative display device according to a comparative example or a comparative embodiment;

FIG. 16 illustrates a folded state of a display device according to another embodiment of the present disclosure;

FIG. 17 is a plan view of a shielding layer according to another embodiment of the present disclosure;

FIG. 18 illustrates a folded state of a display device including the shielding layer illustrated in FIG. 17;

FIGS. 19-21 are plan views of shielding layers according to other embodiments of the present disclosure;

FIG. 22 illustrates a folded state of a display device according to another embodiment of the present disclosure;

FIG. 23 illustrates an unfolded state of the display device illustrated in FIG. 22;

FIG. 24 illustrates a folded state of a display device according to another embodiment of the present disclosure; and

FIG. 25 illustrates a folded state of a display device according to another embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

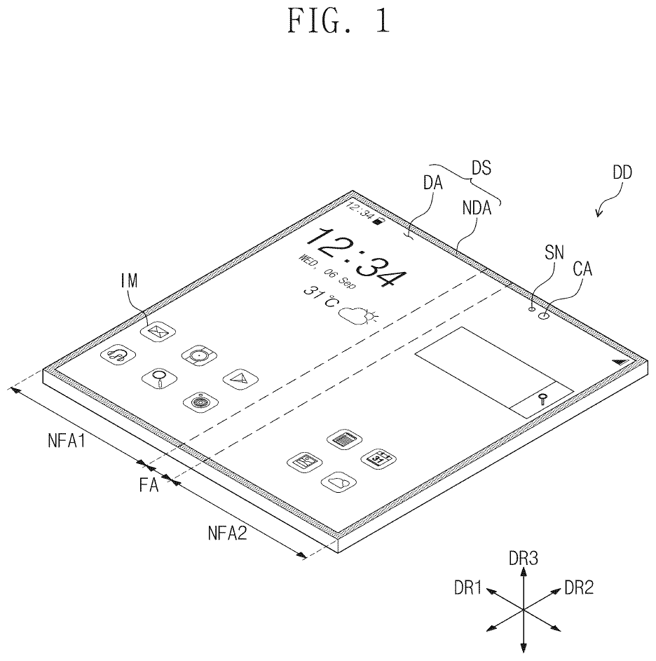

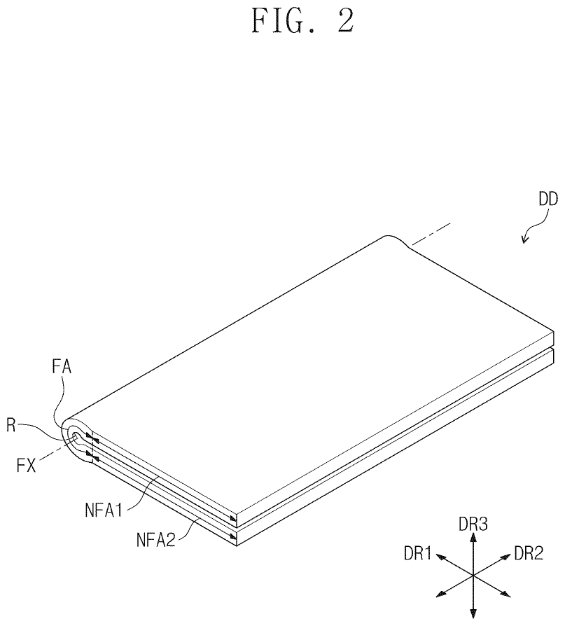

FIG. 1 is a perspective view of a display device according to an embodiment of the present disclosure. FIG. 2 illustrates a folded state of the display device illustrated in FIG. 1.

Referring to FIG. 1, the display device DD according to an embodiment of the present disclosure may have a tetragonal shape having long sides extending in a first direction DR1, and short sides extending in a second direction DR2 crossing the first direction DR1. Without being limited thereto, however, the display device DD may have various suitable shapes, such as a circular shape or a polygonal shape. The display device DD may be a flexible display device.

Hereinafter, a direction perpendicularly or substantially perpendicularly crossing a plane defined by the first direction DR1 and the second direction DR2 is defined as a third direction DR3. In addition, as used herein, the expressions “when viewed on a plane” and “in a plan view” may be defined as a state of being viewed in the third direction DR3.

The display device DD may include a folding region FA, and a plurality of non-folding regions NFA1 and NFA2. The non-folding regions NFA1 and NFA2 may include a first non-folding region NFA1 and a second non-folding region NFA2. The folding region FA may be disposed between the first non-folding region NFA1 and the second non-folding region NFA2. The first non-folding region NFA1, the folding region FA, and the second non-folding region NFA2 may be arranged along the first direction DR1.

As an example, one folding region FA and two non-folding regions NFA1 and NFA2 are illustrated, but the numbers of the folding region FA and the non-folding regions NFA1 and NFA2 are not limited thereto. For example, the display device DD may include more than two non-folding regions, and a plurality of folding regions disposed between the non-folding regions.

The upper surface of the display device DD may be defined as a display surface DS, and the display surface DS may have a plane defined by the first direction DR1 and the second direction DR2. Images IM generated in the display device DD may be provided to a user through the display surface DS.

The display surface DS may include a display region DA, and a non-display region NDA surrounding (e.g., around a periphery of) the display region DA. The display region DA may display an image, and the non-display region NDA may not display an image. The non-display region NDA may surround (e.g., around a periphery of) the display region DA, and may define an edge of the display device DD, which is printed in a suitable color (e.g., a predetermined color).

The display device DD may include at least one sensor SN and at least one camera CA. The sensor SN and the camera CA may be adjacent to an edge of the display device DD. The sensor SN and the camera CA may be disposed in the display region DA adjacent to the non-display region NDA. The sensor SN and the camera CA may be disposed in the second non-folding region NFA2, but the present disclosure is not limited thereto, and the sensor SN and the camera CA may be disposed in the first non-folding region NFA1.

Light may be transmitted through portions of the display device DD, in which the sensor SN and the camera CA are disposed, and may be provided to the camera CA and the sensor SN. As an example, the sensor SN may be a proximity-illuminance sensor, but the kind of sensor SN is not limited thereto. The camera CA may capture an external image. The sensor SN and the camera CA may be provided in a plurality.

Referring to FIG. 2, the display device DD may be a foldable display device DD that is folded or unfolded. For example, the display device DD may be folded when the folding region FA is bent based on a folding axis FX that is parallel to or substantially parallel to the second direction DR2. The folding axis FX may be defined as a long axis that is parallel to or substantially parallel to the long side of the display device DD. Without being limited thereto, however, the folding axis FX may be defined as a short axis parallel to or substantially parallel to the short side of the display device DD, and the display device DD may be folded around the folding axis FX that is parallel to or substantially parallel to the short side thereof.

When the display device DD is folded, the first non-folding region NFA1 and the second non-folding region NFA2 may face each other, and the display device DD may be in-folded so that the display surface DS is not exposed to the outside. However, the present disclosure is not limited thereto. For example, the display device DD may be out-folded around the folding axis FX so that the display surface DS is exposed to the outside.

A distance between the first non-folding region NFA1 and the second non-folding region NFA2 may be smaller than a diameter of a circle defined by a curvature radius R of the folding region FA. In this case, the folding region FA may be folded into a dumbbell shape, and the distance between the first non-folding region NFA1 and the second non-folding region NFA2 may become shorter (e.g., may be decreased).

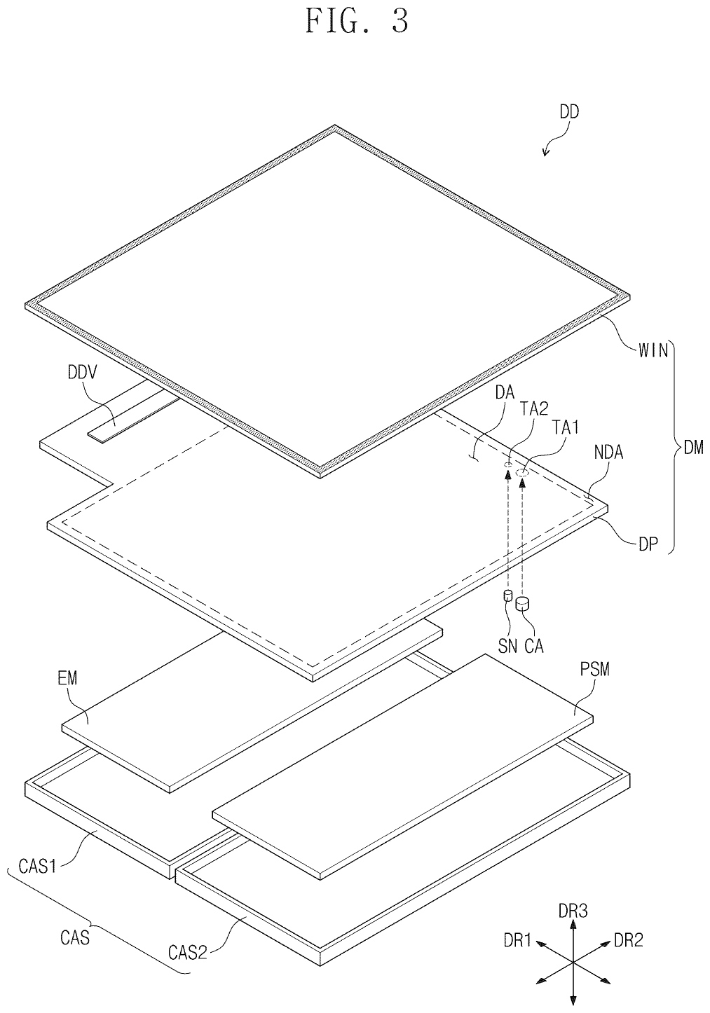

FIG. 3 is an exploded perspective view of the display device illustrated in FIG. 1.

Referring to FIG. 3, the display device DD may include a display module DM (e.g., a display or a touch-display), a camera CA, a sensor SN, an electronic module (e.g., an electronic device or an electronic circuit) EM, a power module (e.g., a power supply or a power circuit) PSM, and a case CAS.

The display module DM may include a window WIN and a display panel DP. As an example, the window WIN and the display panel DP are illustrated in a stacked structure of the display module DM in FIG. 3, but the display module DM may further include various components in addition to the window WIN and the display panel DP. A detailed stacked structure of the display module DM will be described in more detail hereinafter.

The window WIN may provide the front surface of the display device DD. The window WIN may transmit an image generated by the display panel DP, and provide the image to a user.

The display panel DP may include a display region DA and a non-display region NDA corresponding to the display region DA and the non-display region NDA, respectively, of the display device DD (e.g., see FIG. 1). As used herein, the expression “a region/portion corresponds to another region/portion” may mean that they overlap with each other, and may not be limited to having the same area as each other.

A first transmission region TA1 and a second transmission region TA2 may be defined in the display panel DP. The first transmission region TA1 and the second transmission region TA2 may have a higher light transmittance than those of their surroundings. The camera CA may be disposed below the first transmission region TA1, and the sensor SN may be disposed below the second transmission region TA2. Light passing through the first and second transmission regions TA1 and TA2 may be provided to the camera CA and the sensor SN.

The display module DM may include a data driver DDV disposed on the non-display region NDA of the display panel DP. The data driver DDV may be manufactured in the form of an integrated circuit chip, and may be mounted on the non-display region NDA. Without being limited thereto, however, the data driver DDV may be mounted on a flexible circuit board that is connected to the display panel DP.

The electronic module EM and the power module PSM may be disposed below the display panel DP. The electronic module EM and the power module PSM may be connected to each other through a separate flexible circuit board. The electronic module EM may control an operation of the display module DM. The power module PSM may supply power to the electronic module EM.

The case CAS may accommodate the display module DM, the electronic module EM, and the power module PSM. The case CAS may include two cases, such as one first case CAS1 and one second case CAS2, to fold the display module DM. The first and second cases CAS1 and CAS2 may extend in the second direction DR2, and may be disposed along the first direction DR1.

The display device DD may further include a hinge structure to connect the first and second cases CAS1 and CAS2 to each other, and to rotate the first and second cases CAS1 and CAS2 so that the display device DD is folded. The case CAS may protect the display module DM, the electronic module EM, and the power module PSM.

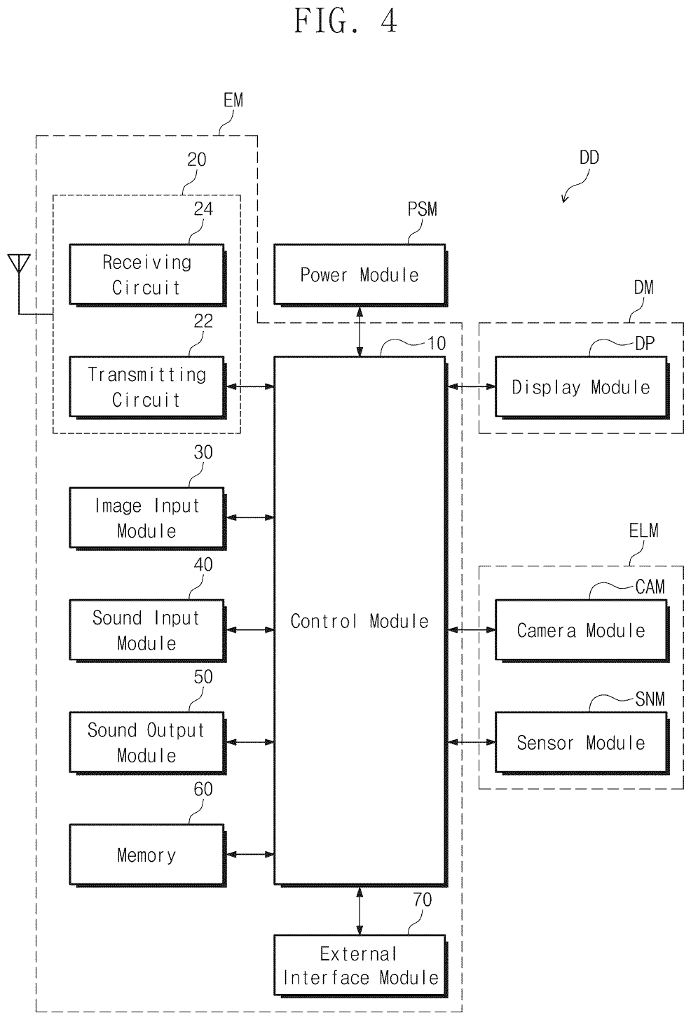

FIG. 4 is a block diagram of the display device illustrated in FIG. 3.

Referring to FIG. 4, the display device DD may include an electronic module (e.g., an electronic device or an electronic circuit) EM, a power module (e.g., a power supply or a power circuit) PSM, a display module (e.g., a display or a touch-display) DM, and an electro-optical module (e.g., an electro-optical device, sensor, or circuit) ELM. The electronic module EM may include a control module (e.g., a controller) 10, a wireless communication module (e.g., a wireless communication device or circuit) 20, an image input module (e.g., an image input device or circuit) 30, a sound input module (e.g., a sound input device or circuit) 40, a sound output module (e.g., a sound output device or circuit) 50, a memory 60, an external interface module (e.g., an external interface device or circuit) 70, and the like. The modules may be mounted on a circuit board or electrically connected to each other through a flexible circuit board. The electronic module EM may be electrically connected to the power module PSM.

The control module 10 may control the overall operations of the display device DD. For example, the control module 10 may activate or deactivate the display module DM in accordance with a user input. The control module 10 may control the image input module 30, the sound input module 40, the sound output module 50, and the like in accordance with a user input. The control module 10 may include at least one microprocessor.

The wireless communication module 20 may transmit/receive wireless signals to/from other terminals by using Bluetooth or a Wi-Fi line. The wireless communication module 20 may transmit/receive voice signals by using a general communication line. The wireless communication module 20 may include a transmitting circuit 22 that modulates a signal to be transmitted and transmits the modulated signal, and a receiving circuit 24 that demodulates the received signal.

The image input module 30 may process image signals to convert them into image data that may be displayed on the display module DM. The sound input module 40 may receive external sound signals by a microphone in a recording mode, a voice recognition mode, or the like, and convert them into electrical voice data. The sound output module 50 may convert sound data received from the wireless communication module 20 or sound data stored in the memory 60, and output the converted sound data to the outside.

The external interface module 70 may serve as an interface that is connected to an external charger, a wired/wireless data port, a card socket (e.g., a memory card, a SIM/UIM card), and/or the like.

The power module PSM may supply power used for the overall operations of the display device DD. The power module PSM may include a general battery device (e.g., a battery).

The electro-optical module ELM may be an electronic component that outputs or receives optical signals. The electro-optical module ELM may transmit or receive optical signals through a partial region of the display module DM. In the present embodiment, the electro-optical module ELM may include a camera module (e.g., a camera) CAM and a sensor module (e.g., a sensor) SNM. The camera module CAM may include the camera CA illustrated in FIG. 3. The sensor module SNM may include the sensor SN illustrated in FIG. 3.

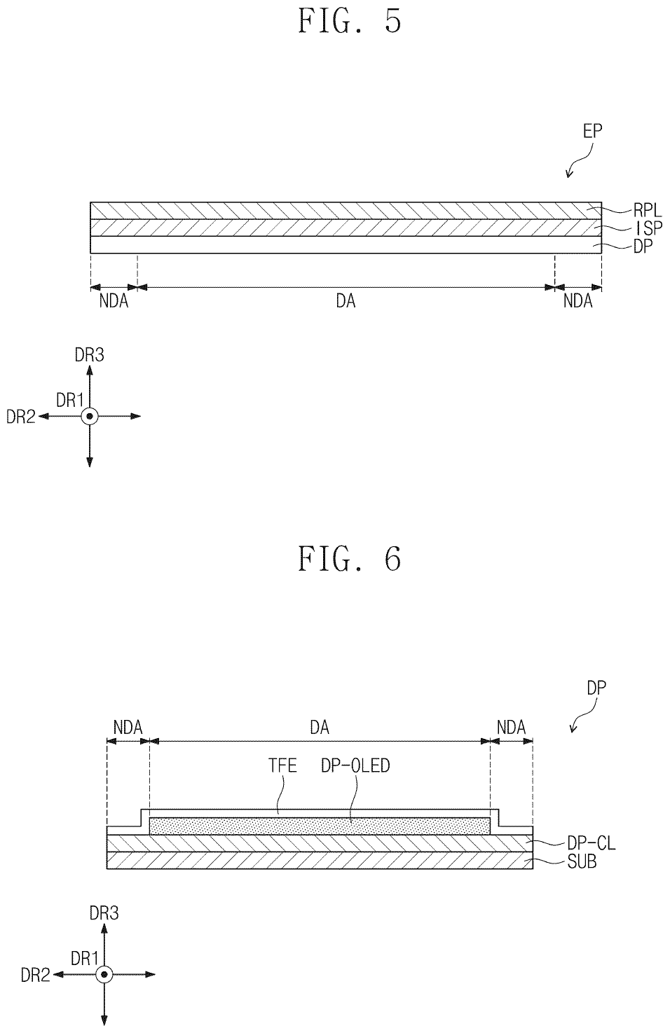

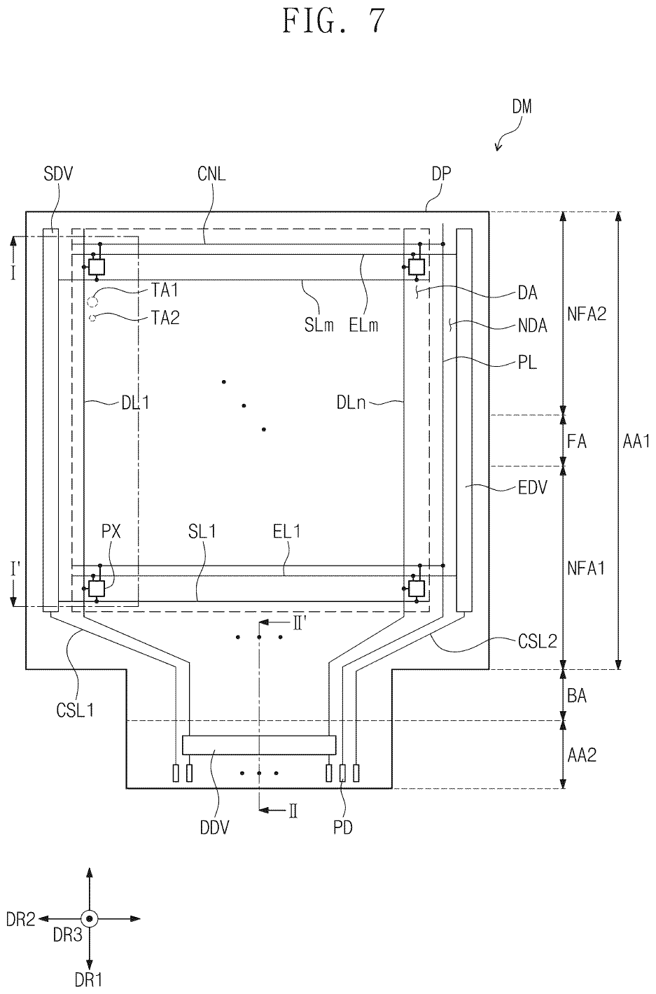

FIG. 5 illustrates a cross-sectional view of an electronic panel including the display panel illustrated in FIG. 3. FIG. 6 illustrates a cross-sectional view of the display panel illustrated in FIG. 5.

As an example, FIGS. 5 and 6 are cross-sectional views viewed in the first direction DR1.

Referring to FIG. 5, the electronic panel EP may include a display panel DP, an input sensing unit (e.g., an input sensing layer or panel) ISP disposed on the display panel DP, and a reflection prevention layer RPL disposed on the input sensing unit ISP. The display module DM described above may include the electronic panel EP.

The display panel DP may be a flexible display panel. The display panel DP according to an embodiment of the present disclosure may be a light-emitting display panel, but the present disclosure is not particularly limited thereto. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include quantum dots, quantum rods, and/or the like. Hereinafter, for convenience, the display panel DP will be described in more detail in the context of an organic light-emitting display panel.

The input sensing unit ISP may include a plurality of sensors for sensing an external input in a capacitive method. The input sensing unit ISP may be manufactured directly on the display panel DP when the display device DD is manufactured. Without being limited thereto, however, the input sensing unit ISP may be manufactured as a panel independent of the display panel DP, and then attached to the display panel DP by an adhesive layer.

The reflection prevention layer RPL may be manufactured directly on the input sensing unit ISP when the display device DD is manufactured. Without being limited thereto, however, the reflection prevention layer RPL may be manufactured as a separate panel, and then attached to the input sensing unit ISP by an adhesive layer.

The reflection prevention layer RPL may be defined as an external light reflection prevention film. The reflection prevention layer RPL may reduce a reflectance of external light incident from above the display device DD toward the display panel DP.

Referring to FIG. 6, the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

The substrate SUB may include a display region DA, and a non-display region NDA surrounding (e.g., around a periphery of) the display region DA. The substrate SUB may include glass or a flexible plastic material, such as polyimide (PI). The display element layer DP-OLED may be disposed on the display region DA.

A plurality of pixels may be disposed in the circuit element layer DP-CL and the display element layer DP-OLED. Each of the pixels may include a transistor disposed in the circuit element layer DP-CL, and a light-emitting element disposed in the display element layer DP-OLED and connected to the transistor.

The thin film encapsulation layer TFE may be disposed on the circuit element layer DP-CL so as to cover the display element layer DP-OLED. The thin film encapsulation layer TFE may protect the pixels from moisture, oxygen, and external foreign substances.

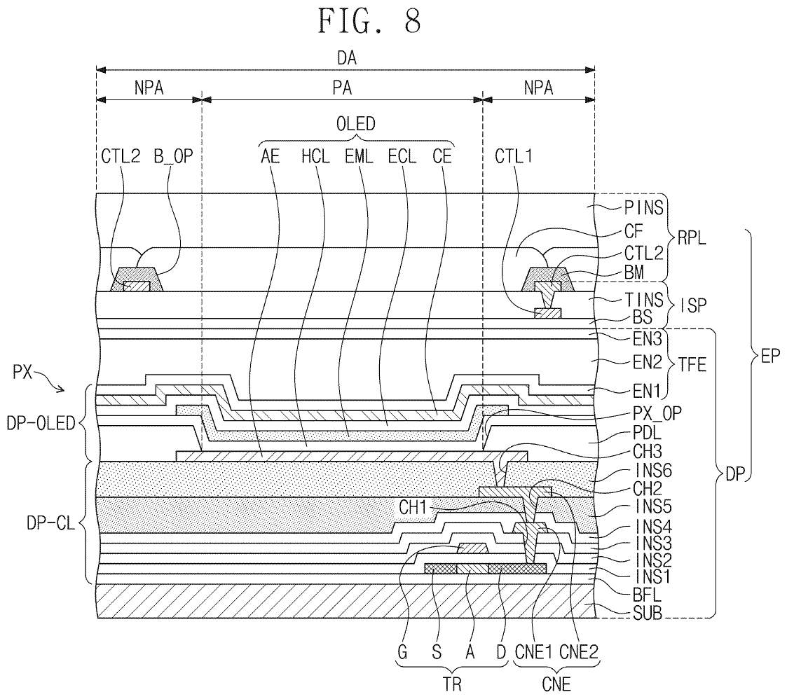

FIG. 7 is a plan view of the display panel illustrated in FIG. 3.

Referring to FIG. 7, the display module DM may include a display panel DP, a scan driver SDV, a data driver DDV, and a light-emitting driver EDV.

The display panel DP may include a first region AA1, a second region AA2, and a bending region BA between the first region AA1 and the second region AA2. The bending region BA may extend in the second direction DR2, and the first region AA1, the bending region BA, and the second region AA2 may be arranged along the first direction DR1.

The first region AA1 may include a display region DA, and a non-display region NDA surrounding (e.g., around a periphery of) the display region DA. The non-display region NDA may surround (e.g., around a periphery of) the display region DA. The display region DA may display an image, and the non-display region NDA may not display an image. The second region AA2 and the bending region BA may not display an image.

When viewed in the second direction DR2, the first region AA1 may include a first non-folding region NFA1, a second non-folding region NFA2, and a folding region FA between the first and second non-folding regions NFA1 and NFA2. The first and second non-folding regions NFA1 and NFA2 and the folding region FA may correspond to the first and second non-folding regions NFA1 and NFA2 and the folding region FA, respectively, of the display device DD illustrated in FIG. 1. The first and second transmission regions TA1 and TA2 may be defined in the display region DA and the second non-folding region NFA2.

The first region AA1 may be folded by being bent based on the above-described folding axis FX. For example, the display panel DP may be folded when the folding region FA of the first region AA1 is folded based on the above-described folding axis FX.

The display panel DP may include a plurality of pixels PX, a plurality of scan lines SL1 to SLm, a plurality of data lines DL1 to DLn, a plurality of light-emitting lines EL1 to ELm, first and second control lines CSL1 and CSL2, a power line PL, a plurality of connection lines CNL, and a plurality of pads PD, wherein m and n are natural numbers. The pixels PX may be disposed in the display region DA, and may be connected to the scan lines SL1 to SLm, the data lines DL1 to DLn, and the light-emitting lines EL1 to ELm.

The scan driver SDV and the light-emitting driver EDV may be disposed in the non-display region NDA. The scan driver SDV and the light-emitting driver EDV may be disposed in the non-display region NDA adjacent to both sides (e.g., opposite sides) of the first region AA1, respectively, which are opposite to each other in the second direction DR2. The data driver DDV may be disposed in the second region AA2. The data driver DDV may be manufactured in the form of an integrated circuit chip, and may be mounted on the second region AA2.

The scan lines SL1 to SLm may extend in the second direction DR2 to be connected to the scan driver SDV. The data lines DL1 to DLn may extend in the first direction DR1 to be connected to the data driver DDV via the bending region BA. The data driver DDV may be connected to the pixels PX through the data lines DL1 to DLn. The light-emitting lines EL1 to ELm may extend in the second direction DR2 to be connected to the light-emitting driver EDV.

The power line PL may extend in the first direction DR1 to be disposed in the non-display region NDA. The power line PL may be disposed between the display region DA and the light-emitting driver EDV. The power line PL may extend to the second region AA2 via the bending region BA. The power line PL may extend toward the lower end of the second region AA2 when viewed on a plane (e.g., in a plan view). The power line PL may receive a driving voltage.

The connection lines CNL may extend in the second direction DR2, and be arranged along the first direction DR1. The connection lines CNL may be connected to the power line PL and the pixels PX. The driving voltage may be applied to the pixels PX through the power line PL and the connection lines CNL, which are connected to each other.

The first control line CSL1 may be connected to the scan driver SDV, and may extend toward the lower end of the second region AA2 via the bending region BA. The second control line CSL2 may be connected to the light-emitting driver EDV, and may extend toward the lower end of the second region AA2 via the bending region BA. The data driver DDV may be disposed between the first control line CSL1 and the second control line CSL2.

When viewed on a plane (e.g., in a plan view), the pads PD may be disposed to be adjacent to the lower end of the second region AA2. The data driver DDV, the power line PL, the first control line CSL1, and the second control line CSL2 may be connected to the pads PD.

The data lines DL1 to DLn may be connected to corresponding pads PD through the data driver DDV. For example, the data lines DL1 to DLn may be connected to the data driver DDV, and the data driver DDV may be connected to the pads PD corresponding to the data lines DL1 to DLn, respectively.

A printed circuit board may be connected to the pads PD, and a timing controller and a voltage generator may be disposed on the printed circuit board. The timing controller may be manufactured as an integrated circuit chip, and may be mounted on the printed circuit board. The timing controller and the voltage generator may be connected to the pads PD through the printed circuit board.

The timing controller may control operations of the scan driver SDV, the data driver DDV, and the light-emitting driver EDV. The timing controller may generate a scan control signal, a data control signal, and a light-emitting control signal, in response to control signals received from the outside. The voltage generator may generate a driving voltage.

The scan control signal may be provided to the scan driver SDV through the first control line CSL1. The light-emitting control signal may be provided to the light-emitting driver EDV through the second control line CSL2. The data control signal may be provided to the data driver DDV. The timing controller may receive image signals from the outside, convert a data format of the image signals so as to meet an interface specification for the data driver DDV, and provide the converted image signals to the data driver DDV.

The scan driver SDV may generate a plurality of scan signals in response to the scan control signal. The scan signals may be applied to the pixels PX through the scan lines SL1 to SLm. The scan signals may be sequentially applied to the scan lines SL1 to SLm.

The data driver DDV may generate a plurality of data voltages corresponding to the image signals in response to the data control signal. The data voltages may be applied to the pixels PX through the data lines DL1 to DLn. The light-emitting driver EDV may generate a plurality of light-emitting signals in response to the light-emitting control signal. The light-emitting signals may be applied to the pixels PX through the light-emitting lines EL1 to ELm.

The pixels PX may receive the data voltages in response to the scan signals. The pixels PX may display an image by emitting light having a luminance corresponding to the data voltages in response to the light-emitting signals. The light-emitting time of the pixels PX may be controlled by the light-emitting signals.

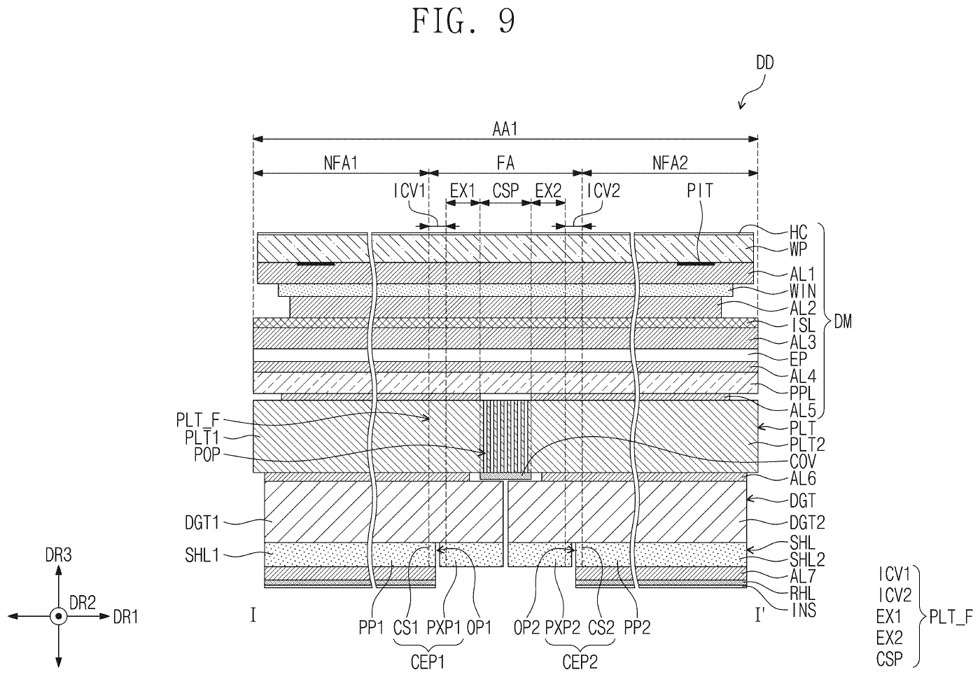

FIG. 8 illustrates a cross-sectional view of the electronic panel corresponding to one pixel illustrated in FIG. 7.

Referring to FIG. 8, the pixel PX may include a transistor TR and a light-emitting element OLED. The light-emitting element OLED may include a first electrode AE (e.g., an anode), a second electrode CE (e.g., a cathode), a hole control layer HCL, an electron control layer ECL, and a light-emitting layer EML.

The transistor TR and the light-emitting element OLED may be disposed on the substrate SUB. Although one transistor TR is illustrated as an example, the pixel PX may include or substantially include a plurality of transistors and at least one capacitor for driving the light-emitting element OLED.

The display region DA may include a light-emitting region PA corresponding to each of the pixels PX, and a non-light-emitting region NPA around (e.g., adjacent to) the light-emitting region PA. The light-emitting element OLED may be disposed in the light-emitting region PA.

A buffer layer BFL may be disposed on the substrate SUB, and the buffer layer BFL may be an inorganic layer. A semiconductor pattern may be disposed on the buffer layer BFL. The semiconductor pattern may include polysilicon, amorphous silicon, or a metal oxide.

The semiconductor pattern may be doped with an N-type dopant or a P-type dopant. The semiconductor pattern may include a highly doped region and a lightly doped region. A conductivity of the highly doped region may be greater than that of the lightly doped region, and the highly doped region may serve or substantially serve as a source electrode and a drain electrode of the transistor TR. The lightly doped region may correspond to or substantially correspond to an active (e.g., a channel) of the transistor.

A source S, an active A, and a drain D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connection electrode CNE may include a first connection electrode CNE1 and a second connection electrode CNE2 to connect the transistor TR and the light-emitting element OLED to each other. The first connection electrode CNE1 may be disposed on the third insulating layer INS3, and connected to the drain D through a first contact hole CH1 defined in (e.g., penetrating) the first to third insulating layers INS1 to INS3.

A fourth insulating layer INS4 may be disposed on the first connection electrode CNE1. A fifth insulating layer INS5 may be disposed on the fourth insulating layer INS4. The second connection electrode CNE2 may be disposed on the fifth insulating layer INS5. The second connection electrode CNE2 may be connected to the first connection electrode CNE1 through a second contact hole CH2 defined in (e.g., penetrating) the fourth and fifth insulating layers INS4 and INS5.

A sixth insulating layer INS6 may be disposed on the second connection electrode CNE2. The layers from the buffer layer BFL to the sixth insulating layer INS6 may be defined as a circuit element layer DP-CL. The first to sixth insulating layers INS1 to INS6 may be inorganic layers or organic layers.

The first electrode AE may be disposed on the sixth insulating layer INS6. The first electrode AE may be connected to the second connection electrode CNE2 through a third contact hole CH3 defined in (e.g., penetrating) the sixth insulating layer INS6. A pixel defining film PDL having an opening PX_OP defined therein to expose a portion (e.g., a predetermined portion) of the first electrode AE may be disposed on the first electrode AE and the sixth insulating layer INS6.

The hole control layer HCL may be disposed on the first electrode AE and the pixel defining film PDL. The hole control layer HCL may include a hole transport layer and/or a hole injection layer.

The light-emitting layer EML may be disposed on the hole control layer HCL. The light-emitting layer EML may be disposed in a region corresponding to the opening PX_OP. The light-emitting layer EML may include an organic material and/or an inorganic material. The light-emitting layer EML may generate any one of red, green, or blue light.

The electron control layer ECL may be disposed on the light-emitting layer EML and the hole control layer HCL. The electron control layer ECL may include an electron transport layer and/or an electron injection layer. The hole control layer HCL and the electron control layer ECL may be commonly disposed in the light-emitting region PA and the non-light-emitting region NPA.

The second electrode CE may be disposed on the electron control layer ECL. The second electrode CE may be commonly disposed in the pixels PX. The layer in which the light-emitting element OLED is disposed may be defined as a display element layer DP-OLED.

The thin film encapsulation layer TFE may be disposed on the second electrode CE and cover the pixel PX. The thin film encapsulation layer TFE may include a first encapsulation layer EN1 disposed on the second electrode CE, a second encapsulation layer EN2 disposed on the first encapsulation layer EN1, and a third encapsulation layer EN3 disposed on the second encapsulation layer EN2.

The first and third encapsulation layers EN1 and EN3 may include an inorganic insulating layer, and may protect the pixel PX from moisture/oxygen. The second encapsulation layer EN2 may include an organic insulating layer, and may protect the pixel PX from foreign substances, such as dust particles.

A first voltage may be applied to the first electrode AE through the transistor TR, and a second voltage having a lower level than that of the first voltage may be applied to the second electrode CE. Holes and electrons injected into the light-emitting layer EML may be combined with each other to form excitons, and the light-emitting element OLED may emit light while the excitons transition to a ground state.

The layers from the substrate SUB to the thin film encapsulation layer TFE may be defined as the display panel DP. The input sensing unit ISP may be disposed on the thin film encapsulation layer TFE. The input sensing unit ISP may be manufactured directly on the upper surface of the thin film encapsulation layer TFE. A base layer BS may be disposed on the thin film encapsulation layer TFE.

The base layer BS may include an inorganic insulating layer. At least one inorganic insulating layer may be provided as the base layer BS on the thin film encapsulation layer TFE.

The input sensing unit ISP may include a first conductive pattern CTL1, and a second conductive pattern CTL2 disposed on the first conductive pattern CTL1. The first conductive pattern CTL1 may be disposed on the base layer BS. An insulating layer TINS may be disposed on the base layer BS so as to cover the first conductive pattern CTL1. The insulating layer TINS may include an inorganic insulating layer or an organic insulating layer. The second conductive pattern CTL2 may be disposed on the insulating layer TINS.

The first and second conductive patterns CTL1 and CTL2 may overlap with the non-light-emitting region NPA. The first and second conductive patterns CTL1 and CTL2 may be disposed on the non-light-emitting region NPA between the light-emitting regions PA (e.g., adjacent to each other), and may have a mesh shape.

The first and second conductive patterns CTL1 and CTL2 may form the sensors of the input sensing unit ISP described above. For example, the mesh-shaped first and second conductive patterns CTL1 and CTL2 may be spaced (e.g., separated) from each other in a suitable region (e.g., a predetermined region) to form the sensors. A portion of the second conductive pattern CTL2 may be connected to the first conductive pattern CTL1.

The reflection prevention layer RPL may be disposed on the second conductive pattern CTL2. The reflection prevention layer RPL may include a black matrix BM and a plurality of color filters CF. The black matrix BM may overlap with the non-light-emitting region NPA, and the color filters CF may overlap with the light-emitting regions PA, respectively.

The black matrix BM may be disposed on the insulating layer TINS so as to cover the second conductive pattern CTL2. An opening B_OP overlapping with the light-emitting region PA and the opening PX_OP may be defined in (e.g., may penetrate) the black matrix BM. The black matrix BM may block light by absorbing the light. The width of the opening B_OP may be larger than the width of the opening PX_OP.

The color filters CF may be disposed on the insulating layer TINS and the black matrix BM. The color filters CF may be disposed in the openings B_OP, respectively. A planarization insulating layer PINS may be disposed on the color filters CF. The planarization insulating layer PINS may provide a flat or substantially flat upper surface.

When external light traveling toward the display panel DP is reflected from the display panel DP like a mirror and provided back to an external user, the user may visually recognize the external light. In order to prevent or reduce such a phenomenon, as an example, the reflection prevention layer RPL may include the color filters CF that display the same or substantially the same colors as those of the pixels of the display panel DP. The color filters CF may filter external light into the same or substantially the same colors as those of the pixels PX. In this case, the external light may not be visible to the user.

However, the present disclosure is not limited thereto, and the reflection prevention layer RPL may include a polarizing film to reduce the reflectance of external light. The polarizing film may be manufactured separately from, and attached to the input sensing unit ISP by an adhesive layer. The polarizing film may include a retarder and/or a polarizer.

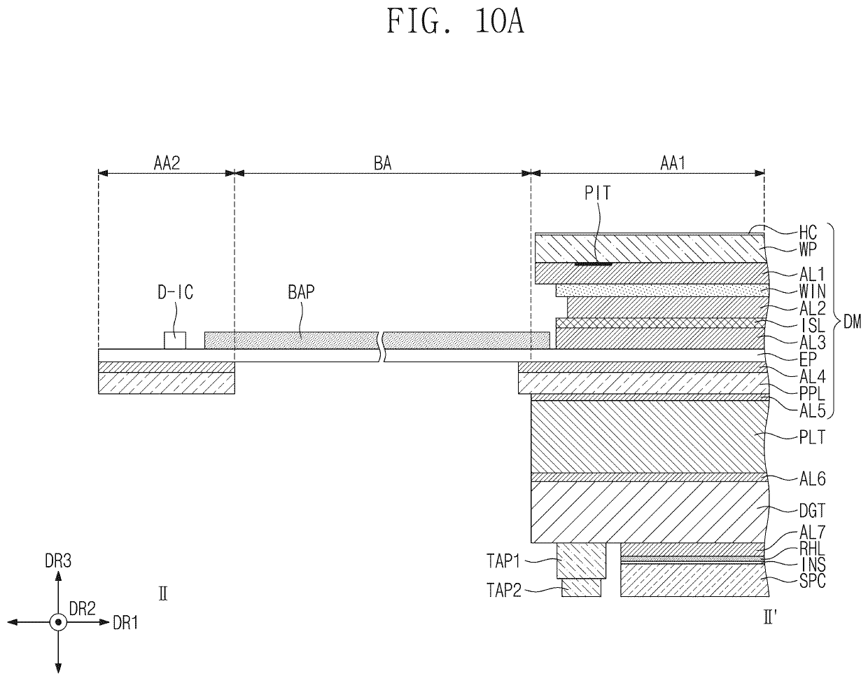

FIG. 9 is a cross-sectional view taken along the line I-I′ illustrated in FIG. 7.

As an example, FIG. 9 illustrates both a cross section of the display module DM corresponding to the line I-I′ and a cross section of the components disposed below (e.g., underneath) the display module DM.

Referring to FIG. 9, the display device DD may include a display module (e.g., a display or a touch-display) DM, a digitizer DGT, a shielding layer SHL, a heat dissipation layer RHL, and an insulating layer INS. The display module DM may include a hard coating layer HC, a printing layer PIT, a window WIN, a window protection layer WP, an impact absorbing layer ISL, an electronic panel EP, and a panel protection layer PPL. The display device DD may include first to seventh adhesive layers AL1 to AL7 for bonding the above-described components to each other.

The display module DM may be a flexible display module. The display module DM may include a first non-folding region NFA1, a folding region FA, and a second non-folding region NFA2. As the folding region FA is folded around the above-described folding axis FX, the display module DM may be folded.

The window WIN may be disposed on the impact absorbing layer ISL. The window WIN may protect the electronic panel EP from external scratches. The window WIN may have optically transparent properties. The window WIN may include glass. Without being limited thereto, however, the window WIN may include a synthetic resin film.

The window WIN may have a multi-layered structure or a single-layer structure. For example, the window WIN may include a plurality of synthetic resin films that are bonded together with an adhesive, or may include a glass substrate and a synthetic resin film that are bonded together with an adhesive.

The window protection layer WP may be disposed on the window WIN. The window protection layer WP may include a flexible plastic material, such as polyimide or polyethylene terephthalate. The hard coating layer HC may be disposed on the upper surface of the window protection layer WP.

The printing layer PIT may be disposed on the lower surface of the window protection layer WP. The printing layer PIT may be black, but the color of the printing layer PIT is not limited thereto. The printing layer PIT may be adjacent to an edge of the window protection layer WP.

The impact absorbing layer ISL may be disposed on the electronic panel EP. The impact absorbing layer ISL may protect the electronic panel EP by absorbing an external impact applied from above the display device DD toward the electronic panel EP. The impact absorbing layer ISL may be manufactured in the form of a stretchable film.

The impact absorbing layer ISL may include a flexible plastic material. The flexible plastic material may be defined as a synthetic resin film. For example, the impact absorbing layer ISL may include a flexible plastic material, such as polyimide (PI) or polyethylene terephthalate (PET).

The panel protection layer PPL may be disposed below the electronic panel EP. The panel protection layer PPL may be disposed below the display panel DP. The panel protection layer PPL may protect the lower portion of the display panel DP. The panel protective layer PPL may include a flexible plastic material. For example, the panel protective layer PPL may include polyethylene terephthalate (PET).

A first adhesive layer AL1 may be disposed between the window protection layer WP and the window WIN. The window protection layer WP and the window WIN may be bonded to each other by the first adhesive layer AL1. The first adhesive layer AL1 may cover the printing layer PIT.

A second adhesive layer AL2 may be disposed between the window WIN and the impact absorbing layer ISL. The window WIN and the impact absorbing layer ISL may be bonded to each other by the second adhesive layer AL2.

A third adhesive layer AL3 may be disposed between the impact absorbing layer ISL and the electronic panel EP. The impact absorbing layer ISL and the electronic panel EP may be bonded to each other by the third adhesive layer AL3.

A fourth adhesive layer AL4 may be disposed between the electronic panel EP and the panel protection layer PPL. The electronic panel EP and the panel protection layer PPL may be bonded to each other by the fourth adhesive layer AL4. A fifth adhesive layer AL5 may be disposed below the panel protection layer PPL.

A support plate PLT may be disposed below and support the display module DM. The support plate PLT may include a non-metal material. For example, the support plate PLT may include a fiber-reinforced composite material. The fiber-reinforced composite material may be carbon fiber reinforced plastic (CFRP) or glass fiber reinforced plastic (GFRP).

The support plate PLT may be made lightweight by including the fiber-reinforced composite material. By including the fiber-reinforced composite material, the support plate PLT according to an embodiment of the present disclosure may have a lighter weight than that of a metal support plate including a metal material, and may have a modulus and strength values that are similar to those of the metal support plate.

Because the support plate PLT includes the fiber-reinforced composite material, the shape processing of the support plate PLT may be easier than that of the metal support plate. For example, the support plate PLT including the fiber-reinforced composite material may be more easily processed through a laser process or a microblasting process.

A plurality of openings POP may be defined in a portion of the support plate PLT overlapping with the folding region FA. The openings POP may be formed to pass through portions of the support plate PLT in the third direction DR3. The openings POP may be formed through the aforementioned laser process or microblasting process.

The support plate PLT may include a first support plate PLT1, a second support plate PLT2, and a folding portion PLT_F. As an example, boundaries between the first support plate PLT1, the second support plate PLT2, and the folding portion PLT_F are illustrated with dotted lines in the support plate PLT.

The folding portion PLT_F may be disposed between the first support plate PLT1 and the second support plate PLT2. The first support plate PLT1, the folding portion PLT_F, and the second support plate PLT2 may be arranged along the first direction DR1. The openings POP may be defined in the folding portion PLT_F.

Hereinafter, as used herein, the term “overlapping” is defined as a state in which portions of components overlap with each other when viewed on a plane (e.g., in a plan view) in a display device disposed in a flat or substantially flat state.

The first support plate PLT1 may be disposed below and overlap with the first non-folding region NFA1. The second support plate PLT2 may be disposed below and overlap with the second non-folding region NFA2. The folding portion PLT_F may be disposed below and overlap with the folding region FA.

The folding portion PLT_F may include a curved surface portion CSP, a first extension portion EX1, a second extension portion EX2, a first reverse curvature portion ICV1, and a second reverse curvature portion ICV2. As an example, the boundaries of the curved surface portion CSP, the first extension portion EX1, the second extension portion EX2, the first reverse curvature portion ICV1, and the second reverse curvature portion ICV2 are illustrated with dotted lines in the support plate PLT, and for convenience, the reference numerals thereof are shown above the display module DM by extending the boundary dotted lines upward.

The curved surface portion CSP, the first extension portion EX1, the second extension portion EX2, the first reverse curvature portion ICV1, and the second reverse curvature portion ICV2 may be arranged along the first direction DR1. As an example, the curved surface portion CSP may be disposed in the central portion of the folding portion PLT_F. The first reverse curvature portion ICV1 may be defined as a portion of the folding portion PLT_F adjacent to the first support plate PLT1. The second reverse curvature portion ICV2 may be defined as a portion of the folding portion PLT_F adjacent to the second support plate PLT2.

The curved surface portion CSP may be disposed between the first extension portion EX1 and the second extension portion EX2. The openings POP may be defined in the curved surface portion CSP. When the folding portion PLT_F is folded, the curved surface portion CSP may be bent to have a desired curvature (e.g., a predetermined curvature). As the openings POP are defined in the curved surface portion CSP, the flexibility of the curved surface portion CSP may be increased. As a result, the curved surface portion CSP may be easily folded.

The first extension portion EX1 may be disposed between the first reverse curvature portion ICV1 and the curved surface portion CSP. The second extension portion EX2 may be disposed between the second reverse curvature portion ICV2 and the curved surface portion CSP.

The first reverse curvature portion ICV1 may be disposed between the first support plate PLT1 and the curved surface portion CSP. In more detail, the first reverse curvature portion ICV1 may be disposed between the first support plate PLT1 and the first extension portion EX1. The second reverse curvature portion ICV2 may be disposed between the second support plate PLT2 and the curved surface portion CSP. In more detail, the second reverse curvature portion ICV2 may be disposed between the second support plate PLT2 and the second extension portion EX2.

A cover layer COV may be disposed below the support plate PLT. The cover layer COV may cover the openings POP defined in the support plate PLT from below (e.g., underneath) the support plate PLT. The cover layer COV may overlap with the curved surface portion CSP of the folding portion PLT_F. The cover layer COV may be in contact with the lower surface of the curved surface portion CSP in which the openings POP are formed.

The cover layer COV may have a lower elastic modulus than that of the support plate PLT. For example, the cover layer COV may include a thermoplastic polyurethane or rubber, but the material of the cover layer COV is not limited thereto. The cover layer COV may be manufactured in the form of a sheet, and attached to the support plate PLT.

The digitizer DGT may be disposed below the support plate PLT. The cover layer COV may be disposed between the support plate PLT and the digitizer DGT. The cover layer COV may be spaced apart from the upper surface of the digitizer DGT.

The digitizer DGT may receive position information indicated by a user on a display surface. The digitizer DGT may be implemented in an electromagnetic method (e.g., an electromagnetic resonance method). For example, the digitizer DGT may include a digitizer sensor substrate including a plurality of coils. Without being limited thereto, however, the digitizer DGT may be implemented in an active electrostatic method.

When a user moves a pen on the display device DD, the pen may be driven by an alternating current signal so as to generate a vibrating magnetic field, and the vibrating magnetic field may induce a signal to the coils. The position of the pen may be detected through the signal induced in the coils. The digitizer DGT may obtain the position of the pen by detecting an electromagnetic change caused by the approach of the pen.

When the support plate PLT disposed on, and adjacent to, the digitizer DGT includes a metal, the sensitivity of the digitizer DGT may be lowered (e.g., may be reduced) by the metal. For example, when a signal transmitted on the display device DD is blocked due to signal interference by a metal support plate, the digitizer DGT may not operate normally.

However, in an embodiment of the present disclosure, because the support plate PLT disposed on the digitizer DGT includes a non-metal fiber-reinforced composite material, the digitizer DGT may operate normally.

The digitizer DGT may be separated into two below (e.g., underneath) the folding portion PLT_F. The digitizer DGT may include a first digitizer DGT1 and a second digitizer DGT2 that are spaced (e.g., separated) from each other and arranged along the first direction DR1. The first digitizer DGT1 may be disposed below the first support plate PLT1, and the second digitizer DGT2 may be disposed below the second support plate PLT2.

The first digitizer DGT1 and the second digitizer DGT2, which are spaced (e.g., separated) from each other, may be connected to a digitizer driver through a flexible circuit board.

The first digitizer DGT1 may overlap with the first support plate PLT1 and a portion of the folding portion PLT_F adjacent to the first support plate PLT1. For example, the first digitizer DGT1 may overlap with the first reverse curvature portion ICV1, the first extension portion EX1, and a portion of the curved surface portion CSP adjacent to the first extension portion EX1.

The second digitizer DGT2 may overlap with the second support plate PLT2 and a portion of the folding portion PLT_F adjacent to the second support plate PLT2. For example, the second digitizer DGT2 may overlap with the second reverse curvature portion ICV2, the second extension portion EX2, and a portion of the curved surface portion CSP adjacent to the second extension portion EX2.

The shielding layer SHL may be disposed below the digitizer DGT. The shielding layer SHL may include a metal. In more detail, the shielding layer SHL may include a magnetic metal powder. The shielding layer SHL may shield an electromagnetism that may be applied to the digitizer DGT from below (e.g., from underneath) the display device DD. The shielding layer SHL may be defined as an electromagnetic shielding layer.

The shielding layer SHL may be in contact with the lower surface of the digitizer DGT. The shielding layer SHL may be directly attached to the lower surface of the digitizer DGT without using an adhesive layer. The shielding layer SHL may be manufactured in the form of a film, and may be directly attached to the lower surface of the digitizer DGT through a hot press process.

When viewed on a plane (e.g., in a plan view), a first opening OP1 adjacent to the first support plate PLT1 and overlapping with the folding portion PLT_F may be defined in the shielding layer SHL. The first opening OP1 may overlap with the first reverse curvature portion ICV1.

When viewed on a plane (e.g., in a plan view), a second opening OP2 adjacent to the second support plate PLT2 and overlapping with the folding portion PLT_F may be defined in the shielding layer SHL. The second opening OP2 may overlap with the second reverse curvature portion ICV2.

Like the digitizer DGT, the shielding layer SHL may be separated into two below (e.g., underneath) the folding portion PLT_F. The shielding layer SHL may include a first shielding layer SHL1 and a second shielding layer SHL2 that are spaced (e.g., separated) from each other and arranged along the first direction DR1.

The first shielding layer SHL1 may be disposed below the first digitizer DGT1, and may be in contact with the lower surface of the first digitizer DGT1. The first opening OP1 may be defined in the first shielding layer SHL1. The second shielding layer SHL2 may be disposed below the second digitizer DGT2, and may be in contact with the lower surface of the second digitizer DGT2. The second opening OP2 may be defined in the second shielding layer SHL2.

The first shielding layer SHL1 may include a first flat portion PP1 and a first bending extension portion CEP1 arranged along the first direction DR1. The second shielding layer SHL2 may include a second flat portion PP2 and a second bending extension portion CEP2 arranged along the first direction DR1. The first bending extension portion CEP1 and the second bending extension portion CEP2 may be disposed below and overlap with the folding portion PLT_F. The first bending extension portion CEP1 and the second bending extension portion CEP2 may be disposed along the first direction DR1.

The first bending extension portion CEP1 may include a first curved surface portion CS1 and a first flat extension portion PXP1 arranged along the first direction DR1. The second bending extension portion CEP2 may include a second curved surface portion CS2 and a second flat extension portion PXP2 arranged along the first direction DR1.

As an example, the boundaries of the first and second flat portions PP1 and PP2, the first and second flat extension portions PXP1 and PXP2, and the first and second curved surface portions CS1 and CS2 are illustrated with dotted lines in the first and second shielding layers SHL1 and SHL2.

The first flat portion PP1 may be disposed below and overlap with the first support plate PLT1. The second flat portion PP2 may be disposed below and overlap with the second support plate PLT2.

The first curved surface portion CS1 may be disposed between the first flat portion PP1 and the first flat extension portion PXP1. The first curved surface portion CS1 may be disposed below and overlap with the first reverse curvature portion ICV1. The first opening OP1 may be defined in the first curved surface portion CS1. The first opening OP1 may be defined in the central portion of the first curved surface portion CS1.

The second curved surface portion CS2 may be disposed between the second flat portion PP2 and the second flat extension portion PXP2. The second curved surface portion CS2 may be disposed below and overlap with the second reverse curvature portion ICV2. The second opening OP2 may be defined in the second curved surface portion CS2. The second opening OP2 may be defined in the central portion of the second curved surface portion CS2.

The first flat extension portion PXP1 may be disposed below the first extension portion EX1 and the curved surface portion CSP, and may overlap with the first extension portion EX1 and a portion of the curved surface portion CSP adjacent to the first extension portion EX1. The second flat extension portion PXP2 may be disposed below the second extension portion EX2 and the curved surface portion CSP, and may overlap with the second extension portion EX2 and a portion of the curved surface portion CSP adjacent to the second extension portion EX2.

The heat dissipation layer RHL may be disposed below the shielding layer SHL. The heat dissipation layer RHL may be separated into two, which may be disposed below the first shielding layer SHL1 and the second shielding layer SHL2, respectively. The heat dissipation layers RHL, which are spaced (e.g., separated) from each other, may be disposed below the first and second flat portions PP1 and PP2, respectively.

The heat dissipation layer RHL may perform a heat dissipation function. For example, the heat dissipation layer RHL may include copper or graphite, but the material of the heat dissipation layer RHL is not limited thereto.

The insulating layer INS may be disposed below the heat dissipation layer RHL. The insulating layer INS may be separated into two, which may be disposed below the two separated heat dissipation layers RHL, respectively. The insulating layer INS may include polyethylene terephthalate (PET).

The fifth adhesive layer AL5 may be disposed between the panel protection layer PPL and the digitizer DGT. The panel protection layer PPL and the digitizer DGT may be bonded to each other by the fifth adhesive layer AL5. The fifth adhesive layer AL5 may not be disposed in a region overlapping with the curved surface portion CSP. The fifth adhesive layer AL5 may be opened in the region overlapping with the curved surface portion CSP.

A sixth adhesive layer AL6 may be disposed between the support plate PLT and the digitizer DGT. The support plate PLT and the digitizer DGT may be bonded to each other by the sixth adhesive layer AL6. The sixth adhesive layer AL6 may be opened in a region overlapping with the folding portion PLT_F. The width of the opening of the sixth adhesive layer AL6 in the first direction DR1 may be larger than the width of the opening of the fifth adhesive layer AL5.

The cover layer COV may be disposed in a region in which the sixth adhesive layer AL6 is opened. Accordingly, the sixth adhesive layer AL6 may be spaced apart from the cover layer COV without being in contact with the cover layer COV. A space in which the cover layer COV is disposed may be secured by the opening of the sixth adhesive layer AL6.

A seventh adhesive layer AL7 may be disposed between the shielding layer SHL and the heat dissipation layer RHL. The shielding layer SHL and the heat dissipation layer RHL may be bonded to each other by the seventh adhesive layer AL7. The seventh adhesive layer AL7 may be separated into two in the folding region FA.

The first to seventh adhesive layers AL1 to AL7 may include a transparent adhesive, such as a pressure sensitive adhesive (PSA) or an optically clear adhesive (OCA), but the kind of adhesive is not limited thereto.

Hereinafter, as used herein, the term “thickness” may represent a value measured in the third direction DR3, and the term “width” may represent a value measured in the first direction DR1 or second direction DR2 which is a horizontal direction.

For example, the thickness of the hard coating layer HC may be about 5 μm, the thickness of the window protection layer WP may be about 65 μm, and the thickness of the first adhesive layer AL1 may be about 50 μm. The thickness of the window WIN may be about 30 μm, the thickness of the second adhesive layer AL2 may be about 50 μm, and the thickness of the impact absorbing layer ISL may be about 23 μm.

The thickness of the third adhesive layer AL3 may be about 50 μm, the thickness of the electronic panel EP may be about 30 μm, and the thickness of the fourth adhesive layer AL4 may be about 25 μm. The thickness of the panel protection layer PPL may be about 50 μm, and the thickness of the fifth adhesive layer AL5 may be about 16 μm.

The thickness of the support plate PLT may be about 170 μm, the thickness of the sixth adhesive layer AL6 may be about 20 μm, and the thickness of the digitizer DGT may be about 144 μm. The thickness of the shielding layer SHL may be about 57 μm, the thickness of the seventh adhesive layer AL7 may be about 31.5 μm, the thickness of the heat dissipation layer RHL may be about 12 μm, and the thickness of the insulating layer INS may be about 6 μm.

The electronic panel EP, the impact absorbing layer ISL, the panel protection layer PPL, and the third and fourth adhesive layers AL3 and AL4 may have the same or substantially the same width as each other. The hard coating layer HC, the window protection layer WP, and the first adhesive layer AL1 may have the same or substantially the same width as each other.

The widths of the electronic panel EP, the impact absorbing layer ISL, the panel protection layer PPL, and the third and fourth adhesive layers AL3 and AL4 may be larger than the widths of the hard coating layer HC, the window protection layer WP, and the first adhesive layer AL1. The edges of the electronic panel EP, the impact absorbing layer ISL, the panel protection layer PPL, and the third and fourth adhesive layers AL3 and AL4 may be disposed more outward than the edges of the hard coating layer HC, the window protection layer WP, and the first adhesive layer AL1.

The widths of the window WIN and the second adhesive layer AL2 may be smaller than the widths of the window protection layer WP and the first adhesive layer AL1. The width of the second adhesive layer AL2 may be smaller than the width of the window WIN. The edge of the window WIN may be disposed more inward than the edges of the window protection layer WP and the first adhesive layer AL1. The edge of the second adhesive layer AL2 may be disposed more inward than the edge of the window WIN. The outer edge of the fifth adhesive layer AL5 may be disposed more inward than the edges of the window protection layer WP and the first adhesive layer AL1.

The width of the support plate PLT may be the same or substantially the same as the width of the electronic panel EP. The outer edge of the digitizer DGT may overlap with the outer edge of the sixth adhesive layer AL6. The outer edges of the digitizer DGT and the sixth adhesive layer AL6 may be disposed more inward than the outer edge of the support plate PLT. The outer edges of the shielding layer SHL, the seventh adhesive layer AL7, the heat dissipation layer RHL, and the insulating layer INS may overlap with the outer edge of the digitizer DGT.

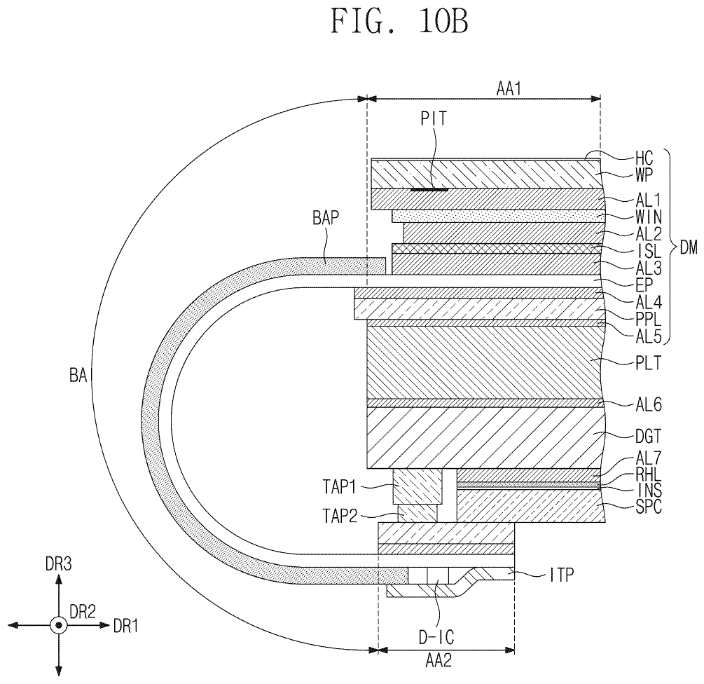

FIG. 10A is a cross-sectional view taken along the line II-II′ illustrated in FIG. 7. FIG. 10B illustrates a bent state of a bending region illustrated in FIG. 10A.

Referring to FIG. 10A, the panel protection layer PPL and the fourth adhesive layer AL4 may not be disposed below the bending region BA. The panel protection layer PPL and the fourth adhesive layer AL4 may be disposed below the second region AA2 of the electronic panel EP. The data driver DDV (e.g., illustrated as an integrated circuit D-IC) may be disposed on the second region AA2 of the electronic panel EP.

The display device DD may further include a bending protection layer BAP. The bending protection layer BAP may be disposed on the bending region BA, a portion of the first region AA1 adjacent to the bending region BA, and a portion of the second region AA2 adjacent to the bending region BA. The bending protection layer BAP may extend continuously from the portion of the first region AA1 adjacent to the bending region BA to the bending region BA and the portion of the second region AA2 adjacent to the bending region BA.

The bending protection layer BAP may be spaced apart from the third adhesive layer AL3. The bending protection layer BAP may be spaced apart from the data driver DDV in the second region AA2. The bending protection layer BAP may include an acrylic-based resin or a urethane-based resin.

The heat dissipation layer RHL and the insulating layer INS may be disposed below a portion of the digitizer DGT adjacent to the bending region BA, and the shielding layer SHL may not be disposed therebelow.

The display device DD may further include a spacer SPC disposed below the insulating layer INS. The thickness of the spacer SPC may be greater than the combined thickness of the seventh adhesive layer AL7, the heat dissipation layer RHL, and the insulating layer INS. The spacer SPC may be a double-sided tape. For example, the spacer SPC may include a base layer containing a flexible material, such as polyethylene terephthalate, and an adhesive disposed on the upper and lower surfaces of the base layer.

The display device DD may further include a first insulating tape TAP1 and a second insulating tape TAP2 disposed below the digitizer DGT between the spacer SPC and one side of the digitizer DGT adjacent to the bending region BA. The first and second insulating tapes TAP1 and TAP2 may include an insulating material.

The first insulating tape TAP1 may be disposed below the digitizer DGT, and attached to the lower surface of the digitizer DGT. The second insulating tape TAP2 may be disposed below the first insulating tape TAP1, and attached to the lower surface of the first insulating tape TAP1. The thickness of the first insulating tape TAP1 may be greater than the thickness of the second insulating tape TAP2. The width of the first insulating tape TAP1 may be greater than the width of the second insulating tape TAP2.

Referring to FIG. 10B, the bending region BA may be bent so as to have a suitable curvature (e.g., a predetermined curvature). When the bending region BA is bent, the second region AA2 may be disposed below (e.g., underneath) the first region AA1. Accordingly, the data driver DDV may be disposed below (e.g., underneath) the first region AA1.

The display device DD may further include an insulating tape ITP disposed below the second region AA2 and covering the data driver DDV. The insulating tape ITP may be disposed below a portion of the bending protection layer BAP disposed below the second region AA2.

The panel protection layer PPL disposed on the second region AA2 may be disposed below the second insulating tape TAP2 and the spacer SPC. The panel protection layer PPL disposed on the second region AA2 may be attached to the second insulating tape TAP2 and the spacer SPC.

The display device DD may include the insulating tape ITP disposed below the second region AA2 and covering the data driver DDV. The insulating tape ITP may be disposed below the portion of the bending protection layer BAP disposed below the second region AA2.

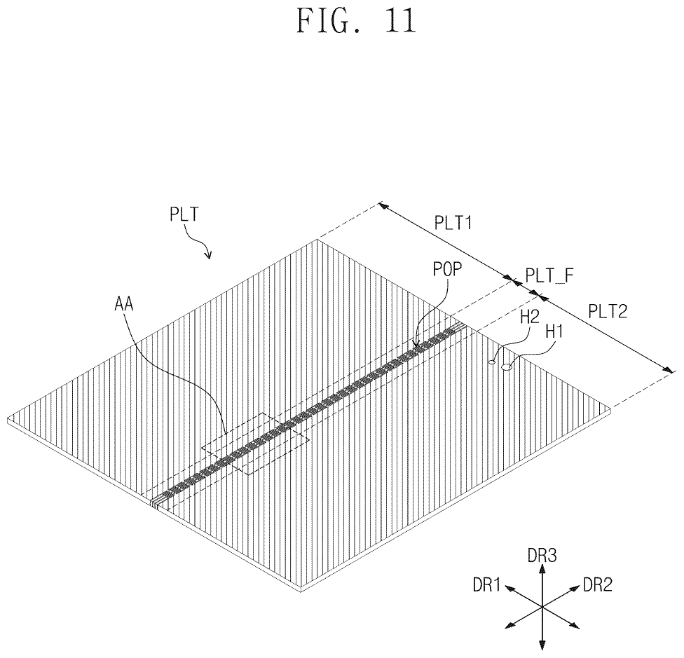

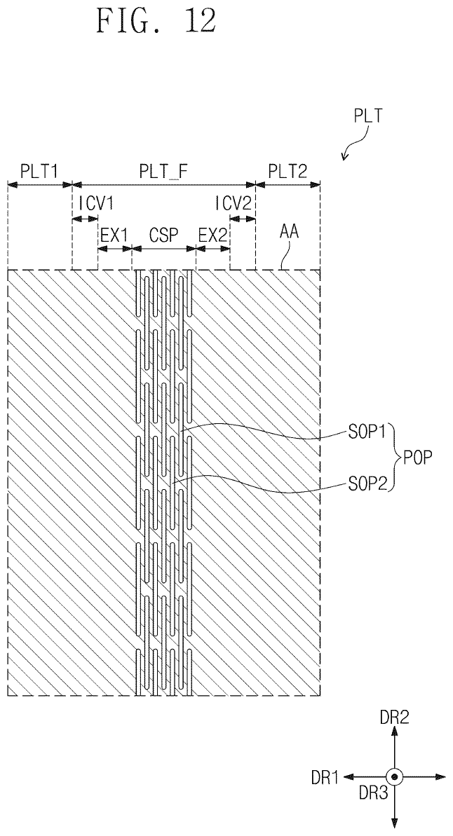

FIG. 11 is a perspective view of the support plate illustrated in FIG. 9. FIG. 12 is an enlarged plan view of the region AA illustrated in FIG. 11.

Referring to FIGS. 11 and 12, the support plate PLT may include a first support plate PLT1, a folding portion PLT_F, and a second support plate PLT2, which are arranged along the first direction DR1. The folding portion PLT_F may include a first reverse curvature portion ICV1, a first extension portion EX1, a curved surface portion CSP, a second extension portion EX2, and a second reverse curvature portion ICV2, which are arranged along the first direction DR1.

A grid pattern may be defined in the curved surface portion CSP. For example, the openings POP defined in the curved surface portion CSP may be arranged according to a suitable rule (e.g., a predetermined rule). The openings POP may be arranged in a grid shape to form the grid pattern of the curved surface portion CSP.

A first hole H1 and a second hole H2 may be defined in (e.g., may penetrate) the second support plate PLT2. The first hole H1 and the second hole H2 may be adjacent to an edge of the second support plate PLT2. The above-described camera CA and sensor SN may be disposed in the first hole H1 and the second hole H2, respectively.

The openings POP may extend longer in the second direction DR2 than in the first direction DR1. The openings POP may include a plurality of first sub-openings SOP1 arranged along the second direction DR2, and a plurality of second sub-openings SOP2 adjacent to the first sub-openings SOP1 in the first direction DR1 and arranged along the second direction DR2. The first sub-openings SOP1 may be arranged to be staggered with the second sub-openings SOP2.

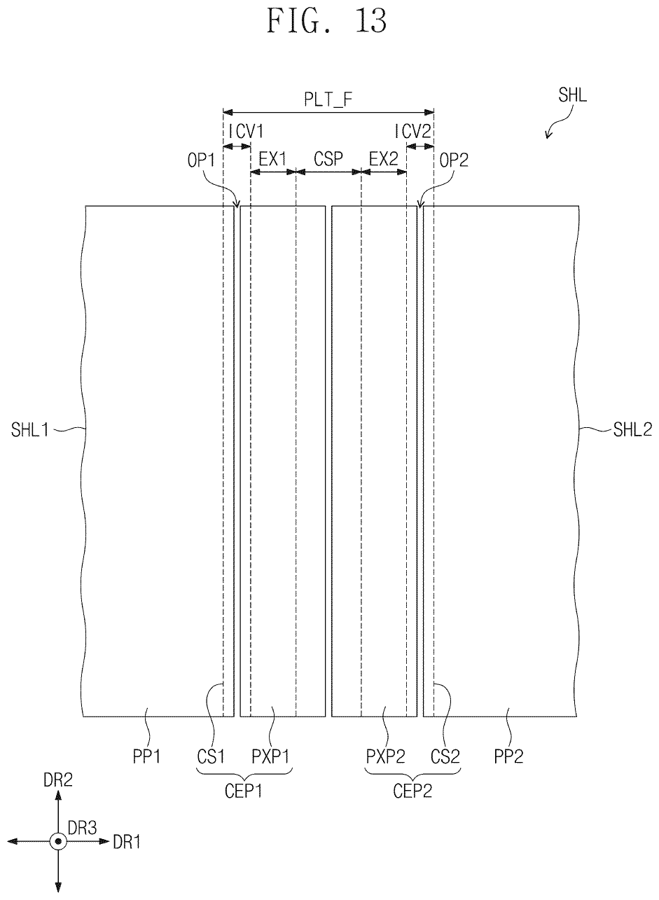

FIG. 13 is a plan view of the shielding layer illustrated in FIG. 9.

As an example, in FIG. 13, the regions of the curved surface portion CSP, the first and second extension portions EX1 and EX2, and the first and second reverse curvature portions ICV1 and ICV2 are illustrated with dotted lines.

Referring to FIG. 13, the first opening OP1 may be defined in the central portion of the first curved surface portion CS1 in the first direction DR1, and extend in the second direction DR2. The second opening OP2 may be defined in the central portion of the second curved surface portion CS2 in the first direction DR1, and extend in the second direction DR2.

The first opening OP1 may open the first shielding layer SHL1 in the second direction DR2 to separate the first shielding layer SHL1. For example, the first opening OP1 may open the first curved surface portion CS1 in the second direction DR2 to separate the first curved surface portion CSP1.

The second opening OP2 may open the second shielding layer SHL2 in the second direction DR2 to separate the second shielding layer SHL2. For example, the second opening OP2 may open the second curved surface portion CS2 in the second direction DR2 to separate the second curved surface portion CS2.

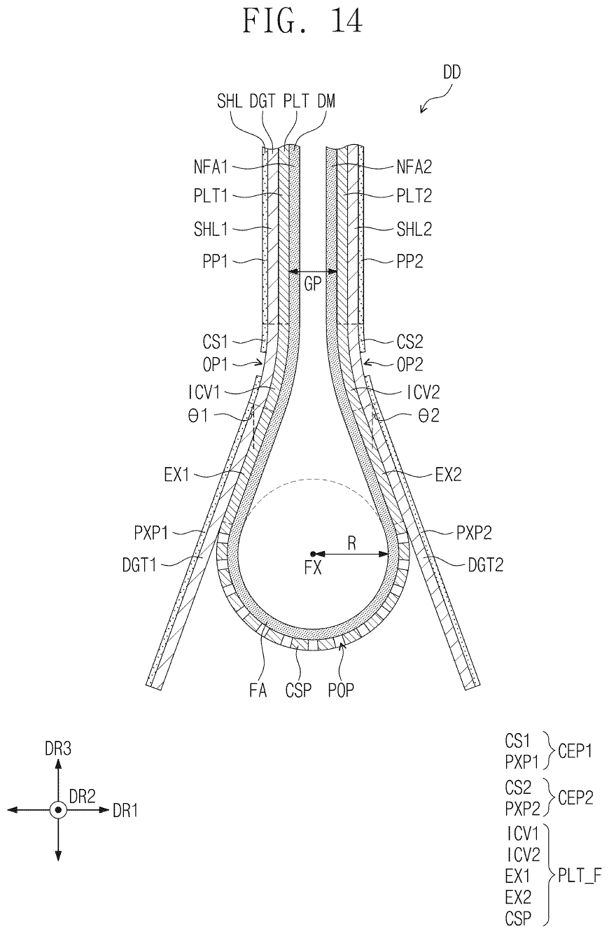

FIG. 14 illustrates a folded state of the display device illustrated in FIG. 9.

For convenience, in FIG. 14, the display module DM is illustrated as a single layer. In addition, for convenience of illustration, the support plate PLT, the digitizer DGT, and the shielding layer SHL are illustrated together with the display module DM, and the other components are omitted.

As an example, the boundaries of the first and second support plates PLT1 and PLT2, the curved surface portion CSP, the first and second extension portions EX1 and EX2, and the first and second reverse curvature portions ICV1 and ICV2 are illustrated with dotted lines in the support plate PLT. In addition, as an example, the boundaries of the first and second flat portions PP1 and PP2, the first and second flat extension portions PXP1 and PXP2, and the first and second curved surface portions CS1 and CS2 are illustrated with dotted lines in the shielding layer SHL.

Referring to FIG. 14, the support plate PLT may be folded around the folding axis FX. The support plate PLT may be folded into a dumbbell shape. As the support plate PLT is folded, the display module DM may be folded together with the support plate PLT.

As the folding portion PLT_F is folded around the folding axis FX, the support plate PLT may be folded. When the folding portion PLT_F is folded, the curved surface portion CSP may be bent so as to have a desired curvature (e.g., a predetermined curvature). For example, the folding region FA of the display module DM on the curved surface portion CSP may be bent so as to have a curvature radius R. As an example, the curvature radius R may be about 1.53 mm.

The first reverse curvature portion ICV1 may be bent in a direction opposite to that of the curved surface portion CSP. The second reverse curvature portion ICV2 may be bent in a direction opposite to that of the curved surface portion CSP. The second reverse curvature portion ICV2 may have a shape symmetrical to or substantially symmetrical to that of the first reverse curvature portion ICV1.

When the folding portion PLT_F is folded, the first support plate PLT1 and the second support plate PLT2 may maintain a flat or substantially flat state. Accordingly, the first and second non-folding regions NFA1 and NFA2 may maintain a flat or substantially flat state by the first and second support plates PLT1 and PLT2.

When the folding portion PLT_F is folded, a distance GP between the first support plate PLT1 and the second support plate PLT2 in the first direction DR1 may be smaller than the diameter of a circle having the curvature radius R. Accordingly, the support plate PLT may be folded into a dumbbell shape.

The first extension portion EX1 may maintain a flat or substantially flat state between the curved surface portion CSP and the first reverse curvature portion ICV1. The first extension portion EX1 may extend in a flat or substantially flat state from the first reverse curvature portion ICV1 toward the curved surface portion CSP.

The second extension portion EX2 may maintain a flat or substantially flat state between the curved surface portion CSP and the second reverse curvature portion ICV2. The second extension portion EX2 may extend in a flat or substantially flat state from the second reverse curvature portion ICV2 toward the curved surface portion CSP.

When the folding portion PLT_F is folded, the first flat portion PP1 and the second flat portion PP2 may maintain a flat or substantially flat state together with the first and second support plates PLT1 and PLT2. A portion of the first digitizer DGT1 between the first flat portion PP1 and the first support plate PLT1 and a portion of the second digitizer DGT2 between the second flat portion PP2 and the second support plate PLT2 may also maintain a flat or substantially flat state.

When the folding portion PLT_F is folded, the first curved surface portion CS1 may be bent together with the first reverse curvature portion ICV1. The first curved surface portion CS1 may be bent into a shape corresponding to the first reverse curvature portion ICV1. A portion of the first digitizer DGT1 overlapping with the first curved surface portion CS1 and the first reverse curvature portion ICV1 may be bent together with the first curved surface portion CS1 and the first reverse curvature portion ICV1.

When the folding portion PLT_F is folded, the second curved surface portion CS2 may be bent together with the second reverse curvature portion ICV2. The second curved surface portion CS2 may be bent into a shape corresponding to the second reverse curvature portion ICV2. A portion of the second digitizer DGT2 overlapping with the second curved surface portion CS2 and the second reverse curvature portion ICV2 may be bent together with the second curved surface portion CS2 and the second reverse curvature portion ICV2.

When the folding portion PLT_F is folded, a portion of the first flat extension portion PXP1 overlapping with the first extension portion EX1 may maintain a flat or substantially flat shape together with the first extension portion EX1. When the folding portion PLT_F is folded, a portion of the second flat extension portion PXP2 overlapping with the second extension portion EX2 may maintain a flat or substantially flat shape together with the second extension portion EX2.

Referring to FIGS. 9 and 14, because the sixth adhesive layer AL6 is not disposed on the curved surface portion CSP, the portions of the first and second digitizers DGT1 and DGT2 overlapping with the curved surface portion CSP may not be bent together with the curved surface portion CSP. In addition, a portion of the first flat extension portion PXP1 overlapping with the curved surface portion CSP and a portion of the second flat extension portion PXP2 overlapping with the curved surface portion CSP may not be bent together with the curved surface portion CSP.

The first flat extension portion PXP1 may extend in a flat state from the first curved surface portion CS1. The second flat extension portion PXP2 may extend in a flat state from the second curved surface portion CS2. The first flat extension portion PXP1 may extend to form a first angle θ1 with respect to the third direction DR3. The second flat extension portion PXP2 may extend to form a second angle θ2 with respect to the third direction DR3. As an example, each of the first angle θ1 and the second angle θ2 may be about 8.92 degrees.

The central portion of the first curved surface portion CS1 in which the first opening OP1 is defined may overlap with or substantially overlap with a portion of the first reverse curvature portion ICV1 having the largest curvature from among the first reverse curvature portion ICV1. In other words, the first opening OP1 may be defined to overlap with the portion of the first reverse curvature portion ICV1 having the largest curvature from among the first reverse curvature portion ICV1.

The central portion of the second curved surface portion CS2 in which the second opening OP2 is defined may overlap with or substantially overlap with a portion of the second reverse curvature portion ICV2 having the largest curvature from among the second reverse curvature portion ICV2. In other words, the second opening OP2 may be defined to overlap with the portion of the second reverse curvature portion ICV2 having the largest curvature from among the second reverse curvature portion ICV2.

Because the first opening OP1 is defined to overlap with the first reverse curvature portion ICV1, the first reverse curvature portion ICV1 may be bent more easily. Because the second opening OP2 is defined to overlap with the second reverse curvature portion ICV2, the second reverse curvature portion ICV2 may be bent more easily.

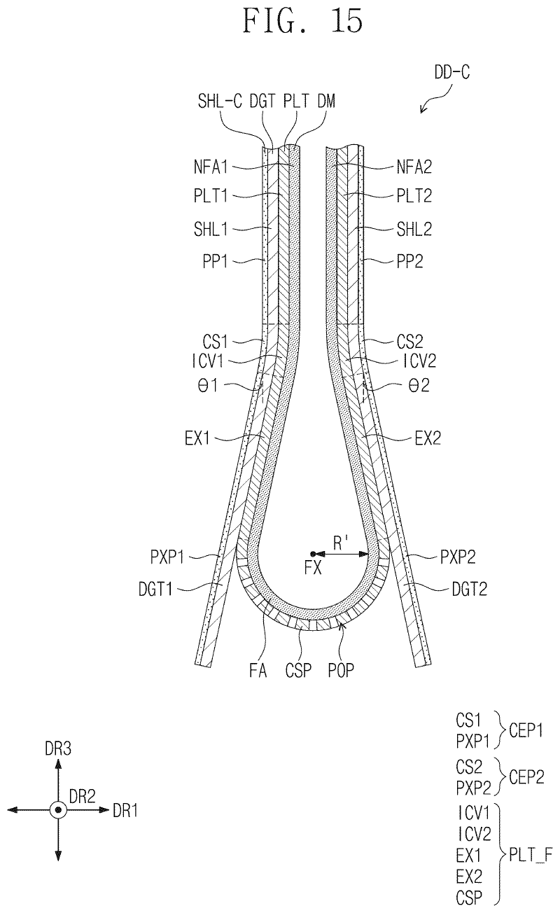

FIG. 15 illustrates a folded state of a comparative display device according to a comparative example or a comparative embodiment.

As an example, FIG. 15 illustrates a cross section corresponding to that of FIG. 14, and the configuration illustrated in FIG. 15 will be described in more detail hereinafter focusing on the components different from those described above with reference to FIG. 14.

Referring to FIG. 15, the first opening OP1 and the second opening OP2 may not be defined in a shielding layer SHL-C of the comparative display device DD-C. Because the first opening OP1 and the second opening OP2 are not defined therein, the first and second reverse curvature portions ICV1 and ICV2 illustrated in FIG. 15 may be bent less than those of the first and second reverse curvature portions ICV1 and ICV2 illustrated in FIG. 14 due to the shielding layer SHL-C.

In this case, the curved surface portion CSP may be bent more to have a larger curvature. Because a curvature radius is inversely proportional to the curvature, the folding region FA of the display module DM on the curved surface portion CSP in FIG. 15 may be bent to have a curvature radius R′ smaller than the curvature radius R illustrated in FIG. 14. As an example, the curvature radius R′ may be about 1.49 mm. In addition, in FIG. 15, each of the first angle θ1 and the second angle θ2 may be about 8.28 degrees.

Referring to FIGS. 14 and 15, stress may be proportional to the curvature. As the curvature of the curved surface portion CSP increases, the display module DM is bent to have a greater curvature, and thus, the stress of the display module DM on the curved surface portion CSP may also increase.

In some embodiments of the present disclosure, because the first and second openings OP1 and OP2 are defined in the shielding layer SHL, the bending characteristics of the first and second reverse curvature portions ICV1 and ICV2 may be improved. As the bending characteristics of the first and second reverse curvature portions ICV1 and ICV2 are improved, the curvature radius of the curved surface portion CSP may be expanded. Accordingly, the stress of the display module DM on the curved surface portion CSP may be reduced.

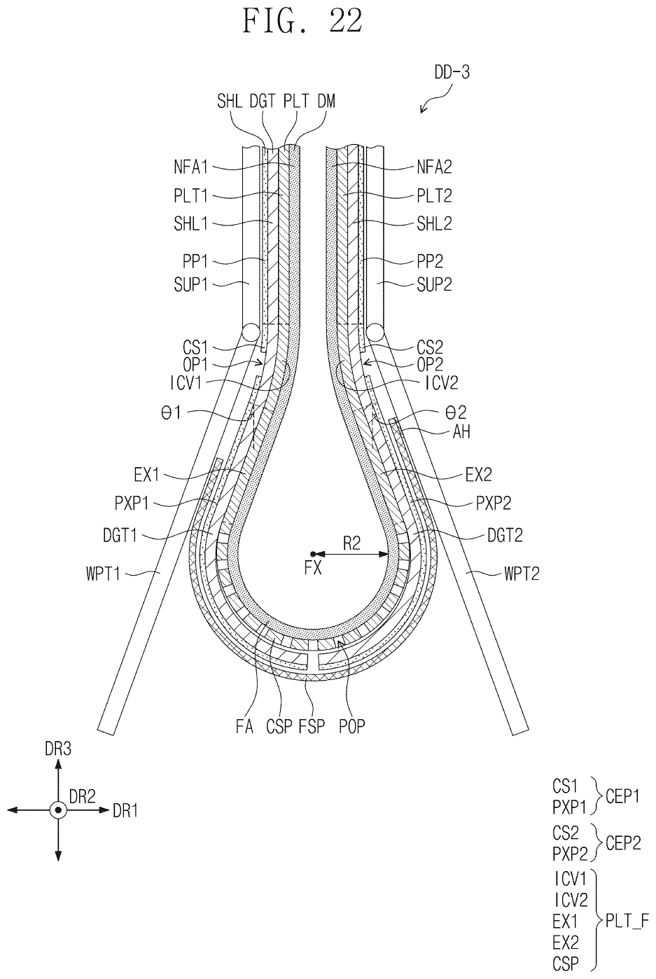

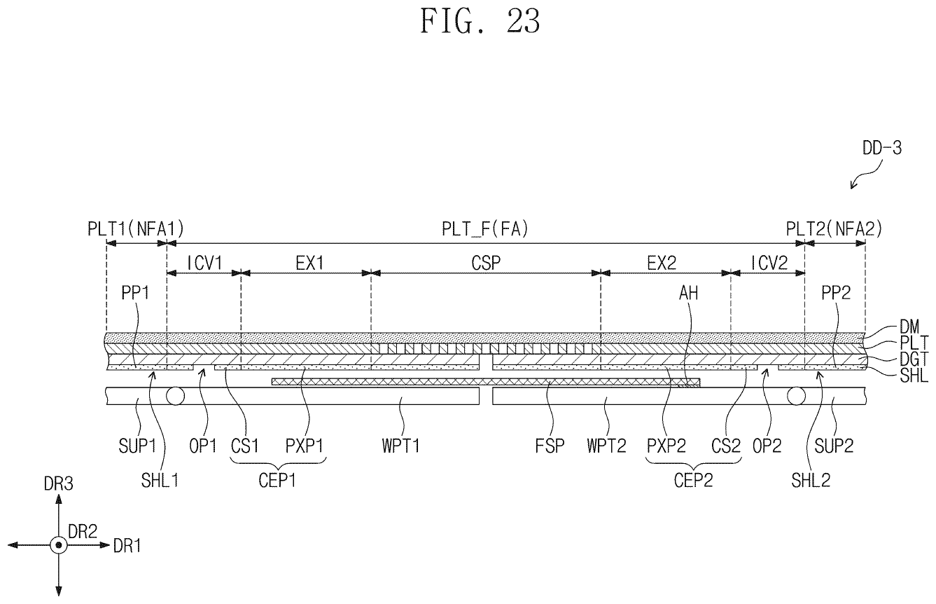

In some embodiments, support structures may support the support plate PLT so that the support plate PLT may maintain a dumbbell shape. A schematic structure of the support structures will be described in more detail below with reference to FIGS. 22 and 23.

In the folded state illustrated in FIG. 14, the support plate PLT maintains a dumbbell shape, but the support plate PLT may have a first repulsive force to return to a “U” shape from the dumbbell shape. In the folded state illustrated in FIG. 15, the support plate PLT maintains a dumbbell shape, but the support plate PLT may have a second repulsive force to return to a “U” shape from the dumbbell shape. When the second repulsion force is set to about 1.0, the first repulsion force may be reduced to about 0.95 when compared to the second repulsion force. In other words, the first repulsive force may be reduced due to the first and second openings OP1 and OP2.

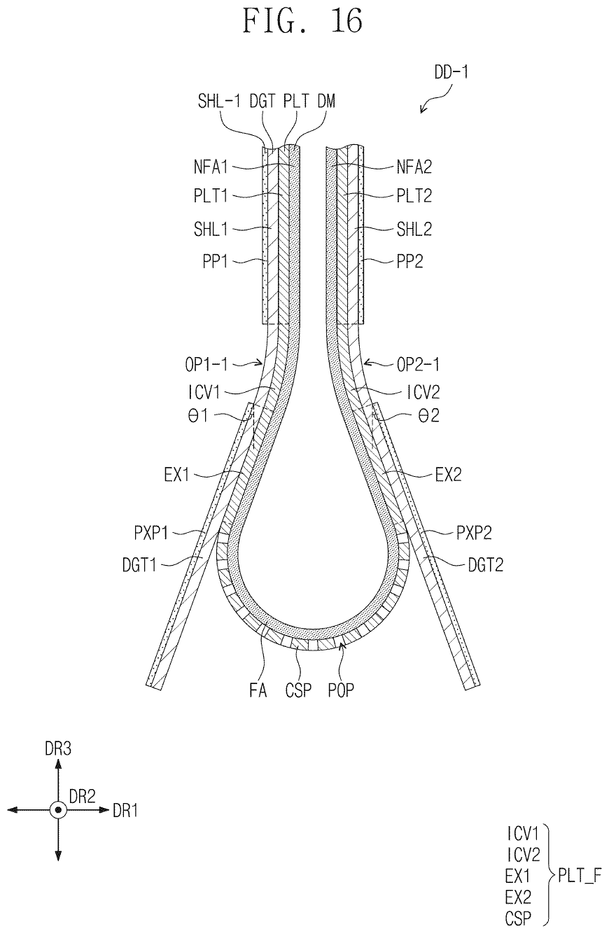

FIG. 16 illustrates a folded state of a display device according to another embodiment of the present disclosure.

As an example, FIG. 16 illustrates a cross section corresponding to that of FIG. 14, and the configuration of a shielding layer SHL-1 of a display device DD-1 illustrated in FIG. 16 will be described in more detail hereinafter focusing on the components different from those described above with reference to FIG. 14.

Referring to FIG. 16, a first opening OP1-1 may be defined to overlap with the entire first reverse curvature portion ICV1. A second opening OP2-1 may be defined to overlap with the entire second reverse curvature portion ICV2. The bending characteristics of the first reverse curvature portion ICV1 may be further improved by the first opening OP1-1. The bending characteristics of the second reverse curvature portion ICV2 may be further improved by the second opening OP2-1.

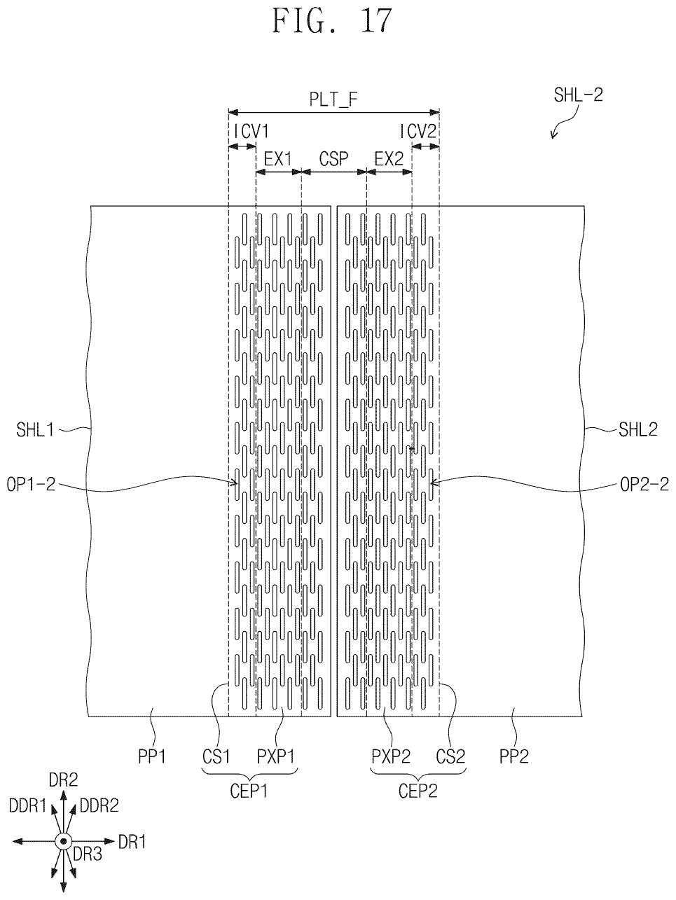

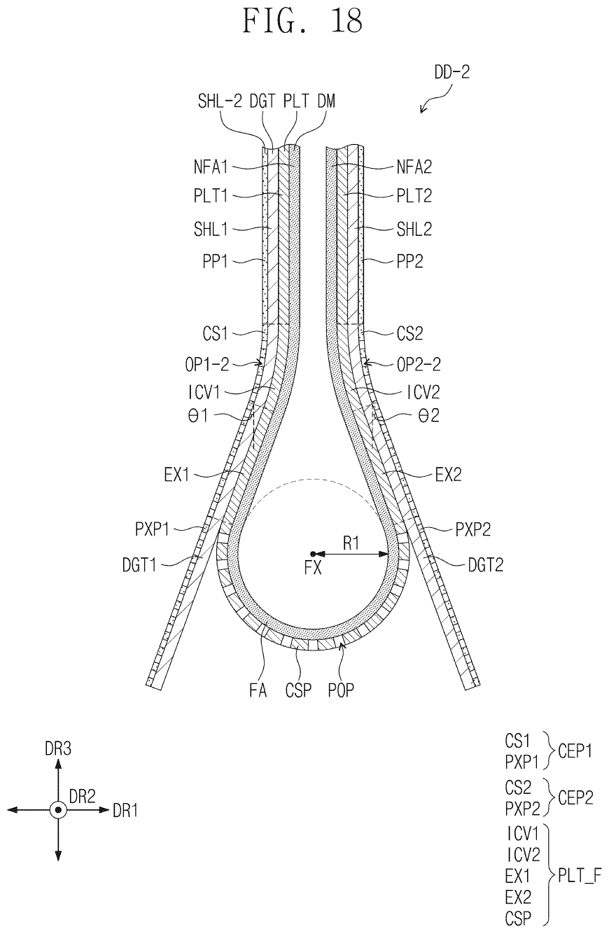

FIG. 17 is a plan view of a shielding layer according to another embodiment of the present disclosure. FIG. 18 illustrates a folded state of a display device including the shielding layer illustrated in FIG. 17.

As an example, FIG. 17 illustrates a plan view corresponding to that of FIG. 13, and FIG. 18 illustrates a cross section corresponding to that of FIG. 14. Hereinafter, the configuration of a shielding layer SHL-2 and a display device DD-2 illustrated in FIGS. 17 and 18 will be described in more detail focusing on the components different from those described above with reference to FIGS. 13 and 14.

Referring to FIGS. 17 and 18, a plurality of first openings OP1-2 may be defined in the first bending extension portion CEP1 overlapping with the folding portion PLT_F. A plurality of second openings OP2-2 may be defined in the second bending extension portion CEP2 overlapping with the folding portion PLT_F.

On a plane defined by the first and second directions DR1 and DR2 (e.g., in a plan view), a direction crossing the first and second directions DR1 and DR2 may be defined as a first diagonal direction DDR1. On a plane defined by the first and second directions DR1 and DR2 (e.g., in a plan view), a direction crossing the first diagonal direction DDR1 may be defined as a second diagonal direction DDR2.

The first openings OP1-2 may be arranged along the first diagonal direction DDR1 and the second diagonal direction DDR2. The second openings OP2-2 may be arranged along the first diagonal direction DDR1 and the second diagonal direction DDR2. The first and second openings OP1-2 and OP2-2 may extend longer in the second direction DR2 than in the first direction DR1.

When the display device DD-2 is folded, the folding region FA of the display module DM on the curved surface portion CSP may be bent to have a first curvature radius R1. As an example, the first curvature radius R1 may be about 1.51 mm. In addition, in FIG. 18, each of the first angle θ1 and the second angle θ2 may be about 8.72 degrees.

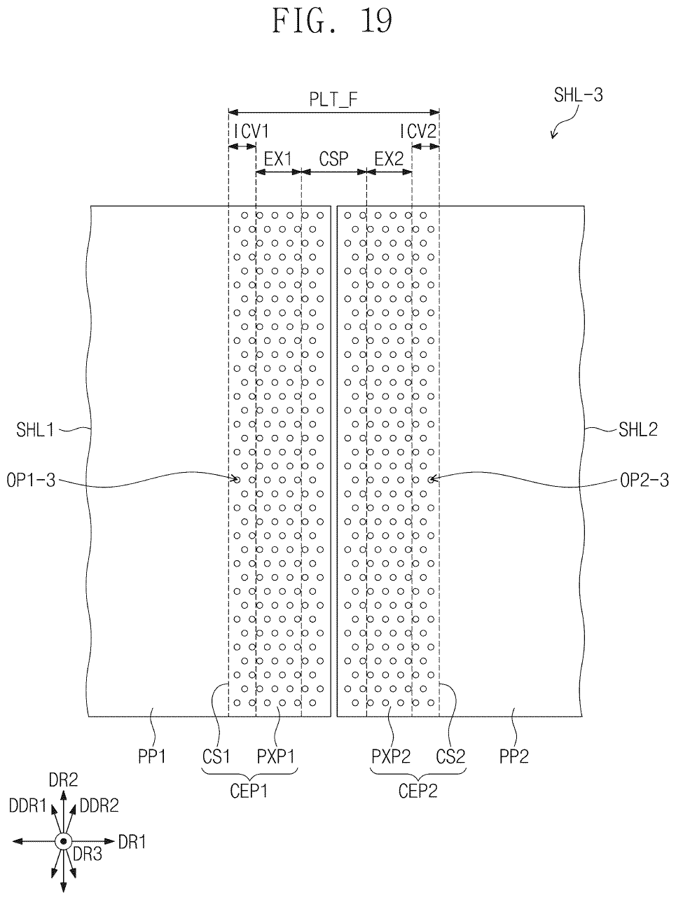

FIGS. 19 through 21 are plan views of shielding layers according to other embodiments of the present disclosure.

As an example, FIGS. 19 through 21 are illustrated as plan views corresponding to that of FIG. 13, and the configurations of the shielding layers SHL-3, SHL-4, and SHL-5 illustrated in FIGS. 19 through 21 will be described in more detail hereinafter focusing on the components different from those described above with reference to FIG. 13.

Referring to FIG. 19, a plurality of first openings OP1-3 may be defined in the first bending extension portion CEP1, and a plurality of second openings OP2-3 may be defined in the second bending extension portion CEP2. The first openings OP1-3 may be arranged along the first diagonal direction DDR1 and the second diagonal direction DDR2. The second openings OP2-3 may be arranged along the first diagonal direction DDR1 and the second diagonal direction DDR2.

The first and second openings OP1-3 and OP2-3 may have a circular shape. Without being limited thereto, however, the first and second openings OP1-3 and OP2-3 may have various suitable shapes, such as an ellipse or a polygon.

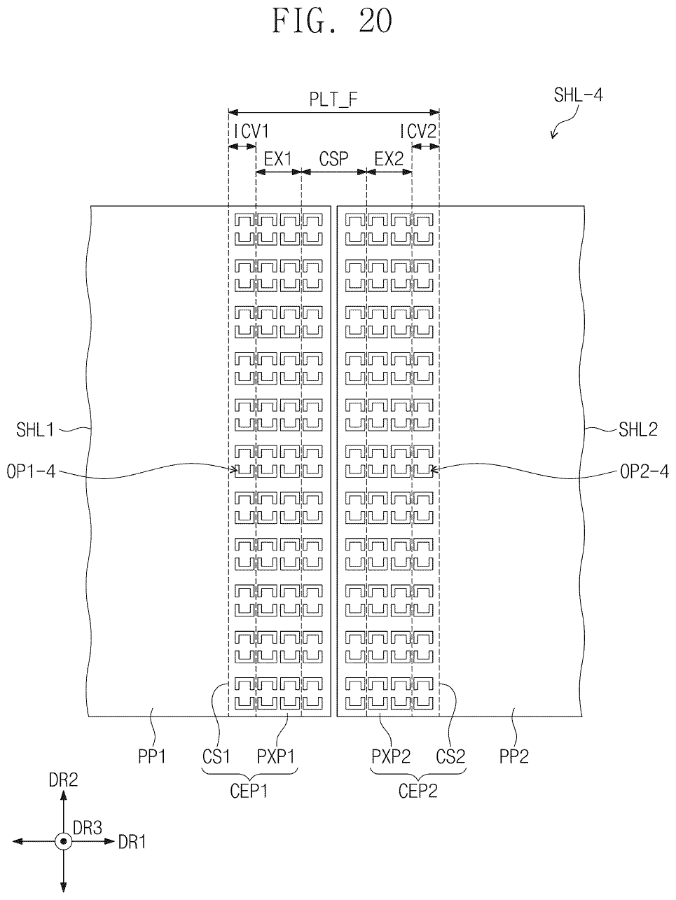

Referring to FIG. 20, a plurality of first openings OP1-4 may be defined in the first bending extension portion CEP1, and a plurality of second openings OP2-4 may be defined in the second bending extension portion CEP2. The first openings OP1-4 may be arranged along the first direction DR1 and the second direction DR2. The second openings OP2-4 may be arranged along the first direction DR1 and the second direction DR2.

The first and second openings OP1-4 and OP2-4 may have a shape bent in a “C” shape. A row may correspond to the first direction DR1. The first and second openings OP1-4 and OP2-4 of an h-th row and the first and second openings OP1-4 and OP2-4 of an (h+1)-th row may have shapes that are symmetrical to or substantially symmetrical to each other in the second direction DR2, where h is a natural number.

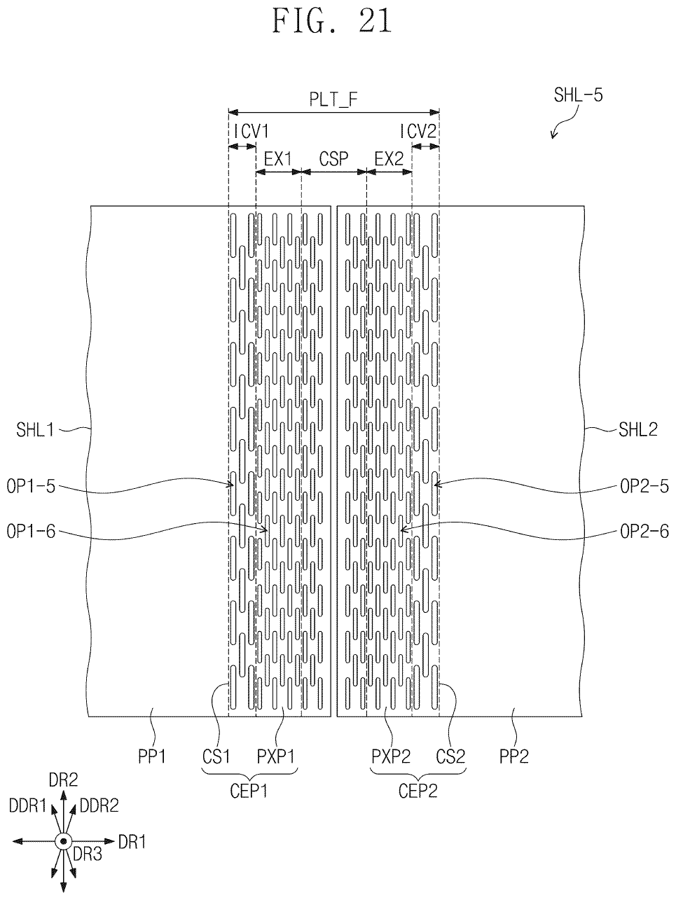

Referring to FIG. 21, a plurality of first openings OP1-5 and OP1-6 may be defined in the first bending extension portion CEP1, and a plurality of second openings OP2-5 and OP2-6 may be defined in the second bending extension portion CEP2.

The first and second openings OP1-5 and OP2-5 defined in the first and second curved surface portions CS1 and CS2 may be formed to be larger than the first and second openings OP1-6 and OP2-6 defined in the first and second flat extension portions PXP1 and PXP2. Because the first and second openings OP1-5 and OP2-5 are formed to be larger, the bending characteristics of the first and second reverse curvature portions ICV1 and ICV2 overlapping with the first and second curved surface portions CS1 and CS2 may be improved.

FIG. 22 illustrates a folded state of a display device according to another embodiment of the present disclosure. FIG. 23 illustrates an unfolded state of the display device illustrated in FIG. 22.

Referring to FIGS. 22 and 23, a display device DD-3 may include first and second support portions SUP1 and SUP2, first and second wing plates WPT1 and WPT2, and a folding support portion FSP. A shielding layer SHL illustrated in FIGS. 22 and 23 may be the same or substantially the same as the shielding layer SHL described above with reference to FIG. 14.

Hereinafter, a stacked structure of the display device DD-3 will be described in more detail assuming that the display device DD-3 illustrated in FIG. 23 is in an unfolded state.

The first support portion SUP1 and the first wing plate WPT1 may be disposed below the first shielding layer SHL1. The second support portion SUP2 and the second wing plate WPT2 may be disposed below the second shielding layer SHL2.

The first support portion SUP1 may be disposed below the first flat portion PP1, and the second support portion SUP2 may be disposed below the second flat portion PP2. The first wing plate WPT1 may be disposed below the first bending extension portion CEP1, and the second wing plate WPT2 may be disposed below the second bending extension portion CEP2. The first wing plate WPT1 and the second wing plate WPT2 may be arranged along the first direction DR1.

The first wing plate WPT1 and the first support portion SUP1 may be connected to (e.g., coupled to or attached to) each other so as to rotate with respect to each other in a region adjacent to the boundary between the first support plate PLT1 and the folding portion PLT_F. The second wing plate WPT2 and the second support portion SUP2 may be connected to (e.g., coupled to or attached to) each other so as to rotate with respect to each other in a region adjacent to the boundary between the second support plate PLT2 and the folding portion PLT_F.

The folding support portion FSP may be disposed between the first wing plate WPT1 and the first bending extension portion CEP1 and between the second wing plate WPT2 and the second bending extension portion CEP2. The folding support portion FSP may be connected to the second wing plate WPT2 and extend onto the first wing plate WPT1. The folding support portion FSP may be connected to the second wing plate WPT2 through an adhesive layer AH. The folding support portion FSP may not be connected to the first wing plate WPT1.

The folding support portion FSP may extend so as to be adjacent to the boundary between the first support plate PLT1 and the folding portion PLT_F and the boundary between the second support plate PLT2 and the folding portion PLT_F.

When the display device DD-3 is folded, the folding support portion FSP may be bent together with the folding portion PLT_F. As the folding support portion FSP is bent, the first and second bending extension portions CEP1 and CEP2 disposed on the folding support portion FSP may also be bent. In addition, the first and second digitizers DGT1 and DGT2 on the first and second bending extension portions CEP1 and CEP2 may also be bent.

Because the folding support portion FSP is not connected to the first wing plate WPT1, when the display device DD-3 is folded and unfolded, the folding support portion FSP may move so as to slide in a space between the first wing plate WPT1 and the first bending extension portion CEP1. The folding support portion FSP may more stably support the folded state of the folding portion PLT_F.

When the folding support portion FSP is disposed below the folding portion PLT_F, the folding region FA of the display module DM on the curved surface portion CSP may be bent so as to have a second curvature radius R2. As an example, the second curvature radius R2 may be about 1.68 mm. In addition, in FIG. 22, each of the first angle θ1 and the second angle θ2 may be about 9.68 degrees.

As an example, the configuration of the folding support portion FSP disposed below the shielding layer SHL illustrated in FIG. 14 has been described, but the present disclosure is not limited thereto, and the folding support portion FSP may be disposed below the shielding portions SHL-C, SHL-1, SHL-2, SHL-3, SHL-4, and SHL-5 described above with reference to FIGS. 15 to 21.

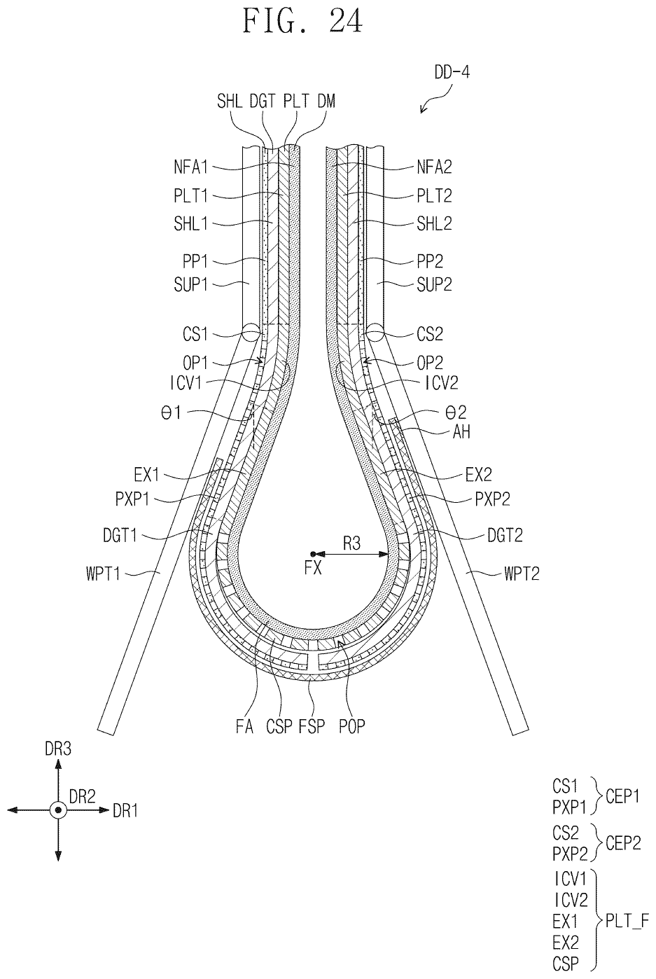

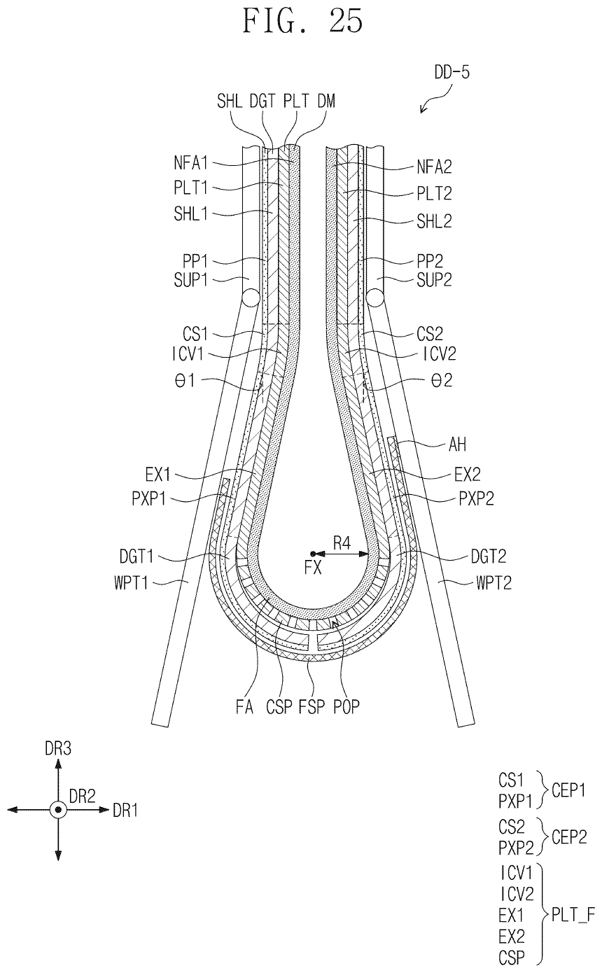

As an example, the configuration of the folding support portion FSP disposed below the shielding layer SHL-2 described above with reference to FIG. 17 and the shielding layer SHL-C described above with reference to FIG. 15 will be described in more detail with reference to FIGS. 24 and 25.

FIG. 24 illustrates a folded state of a display device according to another embodiment of the present disclosure.

As an example, FIG. 24 illustrates a cross section corresponding to that of FIG. 22, and the configuration of a display device DD-4 illustrated in FIG. 24 will be described in more detail hereinafter focusing on the components different from those described above with reference to FIG. 22.

Referring to FIG. 24, the folding support portion FSP may be disposed below the shielding layer SHL-2 in which the first and second openings OP1-2 and OP2-2 illustrated in FIGS. 17 and 18 are defined. Other components of the display device DD-4 may be the same or substantially the same as those of the display device DD-3 described above with reference to FIG. 22.

In this case, the folding region FA of the display module DM on the curved surface portion CSP may be bent so as to have a third curvature radius R3. As an example, the third curvature radius R3 may be about 1.65 mm. In addition, in FIG. 24, each of the first angle θ1 and the second angle θ2 may be about 9.56 degrees.

FIG. 25 illustrates a folded state of a display device according to another embodiment of the present disclosure.

As an example, FIG. 25 illustrates a cross section corresponding to that of FIG. 22, and the configuration of a display device DD-5 illustrated in FIG. 25 will be described in more detail hereinafter focusing on the components different from those described above with reference to FIG. 22.

Referring to FIG. 25, the folding support portion FSP may be disposed below the shielding layer SHL-C in which the first and second openings OP1 and OP2 are not formed. Other components of the display device DD-5 may be the same or substantially the same as those of the display device DD-4 described above with reference to FIG. 22.

In this case, the folding region FA of the display module DM on the curved surface portion CSP may be bent so as to have a fourth curvature radius R4. As an example, the fourth curvature radius R4 may be about 1.61 mm. In addition, in FIG. 25, each of the first angle θ1 and the second angle θ2 may be about 9.02 degrees.

According to one or more embodiments of the present disclosure, openings may be defined in the shielding layer disposed to be in contact with the lower surface of the digitizer, and the openings may overlap with the reverse curvature portions of the folding portion of the support plate for supporting the display module. During a folding operation of the display device, the bending characteristics of the reverse curvature portions may be improved due to the openings, and the curvature radius of the curved surface portion of the folding portion may be expanded. As a result, the stress of the display module on the curved surface portion may be reduced.

The electronic or electric devices and/or any other relevant devices or components according to embodiments of the present invention described herein (e.g., the various modules) may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the exemplary embodiments of the present invention.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a display module;
a support plate below the display module, and comprising a first support plate, a second support plate, and a folding portion between the first and second support plates;
a digitizer below the support plate; and
a shielding layer in contact with a lower surface of the digitizer, and having:
a first opening adjacent to the first support plate and overlapping with the folding portion; and
a second opening adjacent to the second support plate and overlapping with the folding portion.

2. The display device of claim 1, wherein:
the first support plate, the folding portion, and the second support plate are located along a first direction; and
the first opening and the second opening extend in a second direction crossing the first direction.

3. The display device of claim 2, wherein the first opening and the second opening open the shielding layer in the second direction to separate the shielding layer.

4. The display device of claim 1, wherein the digitizer comprises a first digitizer overlapping with the first support plate and a portion of the folding portion adjacent to the first support plate; and
a second digitizer overlapping with the second support plate and a portion of the folding portion adjacent to the second support plate, and
wherein the shielding layer comprises:
a first shielding layer in contact with the lower surface of the first digitizer, and having the first opening defined therein; and
a second shielding layer spaced from the first shielding layer, in contact with the lower surface of the second digitizer, and having the second opening defined therein.

5. The display device of claim 4, wherein the folding portion comprises:
a curved surface portion;
a first reverse curvature portion between the first support plate and the curved surface portion; and
a second reverse curvature portion between the second support plate and the curved surface portion, and
wherein, when the folding portion is folded, the curved surface portion is bent to have a curvature, and the first and second reverse curvature portions are bent in a direction opposite to that of the curved surface portion.

6. The display device of claim 5, wherein the first opening overlaps with a portion of the first reverse curvature portion having the largest curvature from among the first reverse curvature portion.

7. The display device of claim 5, wherein the second opening overlaps with a portion of the second reverse curvature portion having the largest curvature from among the second reverse curvature portion.

8. The display device of claim 5, wherein:
the first shielding layer comprises a first curved surface portion overlapping with the first reverse curvature portion and bent together with the first reverse curvature portion when the folding portion is folded; and
the first opening is in a central portion of the first curved surface portion.

9. The display device of claim 5, wherein:
the second shielding layer comprises a second curved surface portion overlapping with the second reverse curvature portion and bent together with the second reverse curvature portion when the folding portion is folded; and
the second opening is in a central portion of the second curved surface portion.

10. The display device of claim 5, wherein:
the first opening overlaps with the entire first reverse curvature portion; and
the second opening overlaps with the entire second reverse curvature portion.

11. The display device of claim 5, wherein:
the first opening comprises a plurality of first openings;
the second opening comprises a plurality of second openings;
the first shielding layer comprises a first bending extension portion overlapping with the folding portion;
the second shielding layer comprises a second bending extension portion overlapping with the folding portion and located in a direction parallel to the first bending extension portion;
the plurality of first openings are in the first bending extension portion; and
the plurality of second openings are in the second bending extension portion.

12. The display device of claim 11, wherein:
the first support plate, the folding portion, and the second support plate are located along a first direction;
the folding portion is folded around a folding axis extending in a second direction crossing the first direction; and
the plurality of first and second openings are located along a first diagonal direction crossing the first and second directions and a second diagonal direction crossing the first diagonal direction on a plane defined by the first and second directions.

13. The display device of claim 12, wherein the first and second openings extend longer in the second direction than in the first direction.

14. The display device of claim 12, wherein the first and second openings have a circular shape or a polygonal shape.

15. The display device of claim 11, wherein the first bending extension portion comprises:
a first curved surface portion overlapping with the first reverse curvature portion and bent together with the first reverse curvature portion when the folding portion is folded; and
a first flat extension portion overlapping with the folding portion and extending in a flat state from the first curved surface portion,
wherein the second bending extension portion comprises:
a second curved surface portion overlapping with the second reverse curvature portion and bent together with the second reverse curvature portion when the folding portion is folded; and
a second flat extension portion overlapping with the folding portion and extending in a flat state from the second curved surface portion, and
wherein first and second openings in the first and second curved surface portions from among the plurality of first and second openings are larger than first and second openings in the first and second flat extension portions from among the plurality of first and second openings.

16. The display device of claim 5, further comprising:
a first wing plate below the folding portion;
a second wing plate below the folding portion and located in a direction parallel to the first wing plate; and
a folding support portion connected to the second wing plate and extending onto the first wing plate,
wherein:
the first shielding layer comprises a first bending extension portion overlapping with the folding portion;
the second shielding layer comprises a second bending extension portion overlapping with the folding portion and located in a direction parallel to the first bending extension portion;
the first wing plate is located below the first bending extension portion;
the second wing plate is located below the second bending extension portion;
the folding support portion is located between the first wing plate and the first bending extension portion and between the second wing plate and the second bending extension portion; and
the folding support portion extends to be adjacent to a boundary between the first support plate and the folding portion and a boundary between the second support plate and the folding portion.

17. The display device of claim 1, wherein the shielding layer comprises a magnetic metal powder.

18. The display device of claim 1, wherein an edge of the shielding layer overlaps with an edge of the digitizer.

19. A display device comprising:
a display module;
a support plate below the display module, and comprising a first non-folding portion, a second non-folding portion, and a folding portion between the first and second non-folding portions;
a digitizer below the support plate; and
a shielding layer in contact with a lower surface of the digitizer,
wherein the folding portion comprises:
a curved surface portion;
a first reverse curvature portion between the first non-folding portion and the folding portion; and
a second reverse curvature portion between the second non-folding portion and the folding portion,
wherein, when the folding portion is folded, the curved surface portion is bent to have a curvature, and the first and second reverse curvature portions are bent in a direction opposite to the curved surface portion, and
wherein a first opening overlapping with a portion of the first reverse curvature portion having the largest curvature from among the first reverse curvature portion and a second opening overlapping with a portion of the second reverse curvature portion having the largest curvature from among the second reverse curvature portion are defined in the shielding layer.

20. A display device comprising:
a display module;
a support plate below the display module, and comprising a first non-folding portion, a second non-folding portion, and a folding portion between the first and second non-folding portions;
a digitizer below the support plate; and
a shielding layer in contact with a lower surface of the digitizer,
wherein the folding portion comprises:
a curved surface portion;
a first reverse curvature portion between the first non-folding portion and the folding portion; and
a second reverse curvature portion between the second non-folding portion and the folding portion,
wherein, when the folding portion is folded, the curved surface portion is bent to have a curvature, and the first and second reverse curvature portions are bent in a direction opposite to the curved surface portion, and
wherein a first opening overlapping with a central portion of the first reverse curvature portion and a second opening overlapping with a central portion of the second reverse curvature portion are defined in the shielding layer.
